(19) United States
(12) Patent Application Publication
(10) Pub. No.: US 2023/0087216 A1
(43) Pub. Date: Mar. 23, 2023

(54) THERMAL MANAGEMENT SYSTEM

(71) Applicants: NEOGRAF SOLUTIONS, LLC, Lakewood, OH (US); W.L. GORE & ASSOCIATES, INC., Newark, DE (US)

(72) Inventors: Jonathan Taylor, Mayfield Village, OH (US); Lindsey Keen, Middletown, DE (US); Mitchell Warren, Newark, DE (US); John C. Allen, Lincoln University, PA (US); Prashanth Subramanian, Westlake, OH (US)

(21) Appl. No.: 17/802,774

(22) PCT Filed: Feb. 26, 2021
(86) PCT No.: PCT/US2021/019920

§ 371 Date: Aug. 26, 2022

Related U.S. Application Data
(60) Provisional application No. 62/983,243, filed on Feb. 28, 2020.

(51) Int. Cl. H01L 23/373; B32B 5/18; B32B 9/00; B32B 9/04

(52) U.S. Cl. CPC H01L 23/3735; B32B 5/18; B32B 9/007; B32B 9/045; B32B 9/046; B32B 2250/02; B32B 2266/126; B32B 2305/026; B32B 2307/304; B32B 2307/546; B32B 2313/04; B32B 2457/00

(57) ABSTRACT

Thermal management systems are disclosed. One thermal management system includes a first element, a second element adjacent the first element, and an optional third element adjacent the second element and opposed to the first element. The first element and the optional third element include a flexible graphite article, which may have the same or different physical properties. The second element includes an insulation material, such as an aerogel-based insulation material or a porous polymer matrix such as an expanded polytetrafluoroethylene (ePTFE) membrane. Also disclosed are electronic devices that include the thermal management systems to manage the heat generated therein to reduce or eliminate hot spots or for other purposes.

### CROSS-REFERENCE TO RELATED APPLICATIONS

This application claims priority to and the benefit of U.S. Provisional Patent Application No. 62/983,243, filed on Feb. 28, 2020, the entire disclosure of which is incorporated herein by reference.

### FIELD

The present disclosure relates to a thermal management system and electronic devices that include the thermal management system. More specifically, in one embodiment the present disclosure relates to a thermal management system that includes a first element, a second element adjacent the first element, and an optional third element adjacent the second element and opposed to the first element. The first element and the optional third element include a flexible graphite article, which may have the same or different physical properties. The second element includes an insulation material, such as but not limited to an aerogel.

### BACKGROUND

With the development of more and more sophisticated electronic devices, such as cell phones, small laptop computers, sometimes referred to as “netbooks,” electronic or digital assistants, sometimes referred to as “smart phones,” etc., including those capable of increasing processing speeds, display resolution, device features (such as cameras) and higher frequencies, relatively extreme temperatures can be generated. Indeed, with the desire for smaller devices having more complicated power requirements, and exhibiting other technological advances, such as microprocessors and integrated circuits in electronic and electrical components and systems as well as in other devices such as high power optical devices, thermal management is even more important. Microprocessors, integrated circuits, displays, cameras (especially those with integrated flashes), and other sophisticated electronic components typically operate efficiently only under a certain range of threshold temperatures. The excessive heat generated during operation of these components can not only harm their own performance but can also degrade the performance and reliability of other components, especially adjacent components, and the overall system and can even cause system failure. The increasingly wide range of environmental conditions, including temperature extremes, in which electronic systems are expected to operate, exacerbates these negative effects.

In addition, the presence of heat-generating components can create hot spots, areas of higher temperature than surrounding areas. This is certainly true in displays, such as plasma display panels, OLEDs or LCDs, where temperature differentials caused by components or even the nature of the image being generated can cause thermal stresses which reduce the desired operating characteristics and lifetime of the device. In other electronic devices, hot spots can have a deleterious effect on surrounding components and can also cause discomfort to the user, such as a hot spot on the bottom of a laptop case where it sits on a user's lap, or on the touch points on the keyboard, or the back of a cell phone or smartphone, etc. In these circumstances, heat dissipation may not be needed, since the total heat generated by the device is not extreme, but heat spreading may be needed, where the heat from the hot spot is spread more evenly across the device, to reduce or eliminate a hot spot.

Thus, as electronic devices become more complex and generate more heat, and particularly hot spots, thermal management becomes an increasingly important element of the design of electronic devices. Accordingly, there remains a need in the art for effective thermal management systems that can be used in electronic devices to manage the heat generated therein to reduce or eliminate hot spots.

### SUMMARY

Disclosed herein are thermal management systems and electronic devices that include the thermal management system. The thermal management systems of the present invention can be used to effectively manage the heat generated by an electronic device to reduce or eliminate hot spots.

In accordance with an embodiment of the present disclosure, a thermal management system is provided. The thermal management system comprises a first element, a second element, and an optional third element. The first element comprises a flexible graphite article having a thickness of more than 65 microns to 95 microns, an in-plane thermal conductivity of more than 700 W/mK up to 950 W/mK, and a through-plane thermal conductivity of less than 6 W/mK. The second element is adjacent to the first element and comprises an insulation material having a through-plane thermal conductivity of less than 0.025 W/mK. The optional third element is adjacent to the second element and opposed to the first element and comprises a flexible graphite article having a thickness of at least 65 microns up to 500 microns, an in-plane thermal conductivity of more than 700 W/mK, and a through-plane thermal conductivity of less than 6 W/mK.

In accordance with another embodiment of the present disclosure, a thermal management system is provided. The thermal management system comprises a first element, a second element, and an optional third element. The first element comprises a flexible graphite article having a thickness of more than 100 microns up to 500 microns, an in-plane thermal conductivity of more than 1000 W/mK, and a through-plane thermal conductivity of less than 6 W/mK. The second element is adjacent to the first element and comprises an insulation material having a through-plane thermal conductivity of less than 0.025 W/mK. The optional third element is adjacent to the second element and opposed to the first element and comprises a flexible graphite article having a thickness of more than 100 microns up to 500 microns and an in-plane thermal conductivity of more than 1000 W/mK.

In accordance with a further embodiment of the present disclosure, a thermal management system is provided. The thermal management system comprises a first element, a second element, and an optional third element. The first element comprises a flexible graphite article having a thickness of at least 100 microns up to 500 microns, an in-plane thermal conductivity of more than 1000 W/mK, and a through-plane thermal conductivity of less than 6 W/mK. The second element is adjacent to the first element and comprises an insulation material having a through-plane thermal conductivity of less than 0.025 W/mK. The optional third element is adjacent to the second element and opposed to the first element and comprises a flexible graphite article having a thickness of at least 100 microns up to 500 microns and an in-plane thermal conductivity of more than 1000 W/mK.

In accordance with an additional embodiment of the present disclosure, a thermal management system is provided. The thermal management system comprises a first element, a second element, and an optional third element. The first element comprises a flexible graphite article having a thickness of more than 100 microns up to 500 microns, an in-plane thermal conductivity of more than 1000 W/mK, and a through-plane thermal conductivity of less than 6 W/mK. The second element is adjacent to the first element and comprises an insulation material having a through-plane thermal conductivity of less than 0.05 W/mK. The optional third element is adjacent to the second element and opposed to the first element and comprises a flexible graphite article having a thickness of at least 100 microns up to 500 microns and an in-plane thermal conductivity of more than 1000 W/mK.

In accordance with a further additional embodiment of the present disclosure, a thermal management system comprises a first element having a thickness of more than 100 microns up to 500 microns, an in-plane thermal conductivity of more than 1000 W/mK, and a through-plane thermal conductivity of less than 6 W/mK, and a second element comprising an insulation element having a through-plane thermal conductivity of less than 0.15 W/mK. The second element may have a thickness at least equal to the thickness of the first element up to no more than ten times (10×) (preferably no more than seven times (7×), more preferably no more than five times (5×) and even more preferably no more than three times (3×)) the thickness of the first element.

An additional embodiment of a thermal management system of the present disclosure includes a flexible graphite first element having a thickness of at least 100 microns, an in-plane thermal conductivity of more than 1000 W/mK and a through-plane thermal conductivity of no more than 6 W/mK. The embodiment also includes an insulation material second element adjacent the first element, the second element has a through-plane thermal conductivity of no more than 0.05 W/mK.

A further embodiment of a thermal management system of the present disclosure includes a flexible graphite first element having a thickness of at least 100 microns, an in-plane thermal conductivity of at least 1000 W/mK, and a through-plane thermal conductivity of less than 6 W/mK. The embodiment also includes an insulation material second element adjacent the flexible graphite first element, the second element having a through-plane thermal conductivity of less than 0.05 W/mK. The embodiment also includes a flexible graphite third element adjacent the second element, the third element having a thickness of at least 100 microns, an in-plane thermal conductivity of at least 1000 W/mK, and a through-plane thermal conductivity of no more than 6 W/mK.

In accordance with the present disclosure, an electronic device comprising a thermal management system of the present disclosure is provided. The electronic device comprises a heat source, an external surface, and a thermal management system of the present disclosure. The thermal management system is arranged in the electronic device so that either the first element or the optional third element is in operative thermal communication with the heat source and the other of the first element and the optional third element faces the external surface.

### BRIEF DESCRIPTION OF THE DRAWINGS

The present invention will be better understood and its advantages more apparent in view of the following detailed description, especially when read with reference to the appended drawings.

FIG. 1 is a schematic view of an exemplary embodiment of a thermal management system of the present disclosure.

FIG. 1a is a schematic view of an exemplary embodiment of a thermal management system of the present disclosure.

FIG. 2 is a schematic view of an exemplary embodiment of an electronic device that includes a thermal management system of the present disclosure.

FIG. 2a is a schematic view of an exemplary embodiment of an electronic device that includes a thermal management system of the present disclosure.

FIG. 3 is a schematic view of an exemplary embodiment of an electronic device that includes a thermal management system of the present disclosure.

FIG. 3a is a schematic view of an exemplary embodiment of an electronic device that includes a thermal management system of the present disclosure.

FIG. 4 is a schematic view of an exemplary embodiment of an electronic device that includes a thermal management system of the present disclosure.

FIG. 5 is a schematic view of an exemplary embodiment of a thermal management system of the present disclosure.

FIG. 6a is a schematic view of an exemplary embodiment of an electronic device that includes a thermal management system of the present disclosure.

FIG. 6b is a schematic view of an exemplary embodiment of an electronic device that includes a thermal management system of the present disclosure.

FIG. 6c is a schematic view of an exemplary embodiment of an electronic device that includes a thermal management system of the present disclosure.

FIG. 6d is a schematic view of an exemplary embodiment of an electronic device that includes a thermal management system of the present disclosure.

FIG. 6e is a schematic view of an exemplary embodiment of an electronic device that includes a thermal management system of the present disclosure.

FIG. 6f is a schematic view of an exemplary embodiment of an electronic device that includes a thermal management system of the present disclosure.

FIG. 7 is a schematic view of an experimental setup utilized in accordance with Example I of the present disclosure.

FIG. 8 illustrates graphs of the thermal testing of samples in accordance with Example I of the present disclosure.

FIG. 8a illustrates graphs of simulations of Sample 2 from Example I of the present disclosure vs. like-thickness comparative samples.

FIG. 9 shows IR images of screen (A) and back cover (B) of a Google Pixel 3XL device in accordance with Example II of the present disclosure. A numberless temperature scale is shown to indicate directional trends between color and temperature. Surface hot spots are represented by the white areas.

FIG. 10 shows images of screen (A) and back cover (B) of a Google Pixel 3XL device with thermocouples attached via TIMs in accordance with Example II of the present disclosure. Thermocouples were placed precisely to measure temperatures at the surface hot spot locations.

FIG. 11 shows an image of a Google Pixel 3XL device with back cover removed with seven numbered locations at which existing air gap thickness was measured by conformable polymer in accordance with Example II of the present disclosure.

FIG. 12 illustrates physical materials, example configurations of materials, and testing configurations used in accordance with Example II of the present disclosure.

FIG. 13 shows an image of part placement (A) and geometry (B) inside the back cover of a Google Pixel 3XL device in accordance with Example II of the present disclosure.

FIG. 14a illustrates the location of cross section A-A in the Google Pixel 3XL device in accordance with Example II of the present disclosure.

FIG. 14b shows a schematic of section A-A of FIG. 14a through the thickness of the Google Pixel 3XL device.

FIG. 15 illustrates graphs of steady-state back cover hot spot temperature (top) and GPU max temperature (bottom) for all configurations tested in the Google Pixel 3XL device in accordance with Example II of the present disclosure.

FIG. 16 shows zoomed IR images over back cover hot spot for all configurations tested in Google Pixel 3XL device in accordance with Example II of the present disclosure.

FIG. 17 illustrates graphs of transient (smoothed) benchmark score (top), CPU frequency (middle), and GPU frequency (bottom) for air-only, out-of-box throttling (left) and Configuration D5, fixed frequencies (right) in the Google Pixel 3XL device in accordance with Example II of the present disclosure.

FIG. 18 illustrates graphs of steady-state back cover hot spot temperature (top), Slingshot Extreme benchmark score (middle), and Frames per Second (bottom) for air-only, out-of-box throttling and Configuration D5, fixed frequencies in the Google Pixel 3XL device in accordance with Example II of the present disclosure.

### DETAILED DESCRIPTION

Described herein are thermal management systems and electronic devices that include the thermal management system. The thermal management systems of the present invention can be used to effectively manage the heat generated by an electronic device to reduce or eliminate hot spots.

In accordance with some of the embodiments of the present disclosure, the thermal management systems comprise a first element, a second element adjacent to the first element, and an optional third element adjacent to the second element and opposed to the first element. In general, the first element and the optional third element comprise a flexible graphite article (also referred to herein as “a flexible graphite first element” and “a flexible graphite third element”), which may have the same or different physical properties, and the second element comprises an insulation material (also referred to herein as “an insulation material second element”) having a through-plane thermal conductivity of less than 0.15 W/mK, including 0.05 W/mK or less, and preferably less than 0.025 W/mK.

As mentioned, the first element and the optional third element of the thermal management systems of some of the embodiments of the present disclosure each comprise a flexible graphite article. In embodiments of the present disclosure, the flexible graphite article is a flexible graphite sheet. In embodiments of the present disclosure, the flexible graphite article comprises one or more layers of graphite material. In embodiments of the present disclosure, the graphite material used to form the flexible graphite article comprises an expanded graphite sheet (sometimes referred to as a sheet of compressed particles of exfoliated or expanded graphite), a synthetic graphite (e.g., pyrolytic graphite, graphitized polyimide film), and combinations thereof. In embodiments of the present disclosure, the flexible graphite article is monolithic. As used herein, the term “monolithic” refers to a single, unitary structure that does not include an adhesive. Accordingly, a monolithic, flexible graphite article may include one or multiple (e.g., two, three, four) layers of a graphite material, including different graphite materials, that are joined together to form a unitary structure without the use of an adhesive.

Exemplary flexible graphite articles suitable for use in the thermal management systems of the present disclosure are described in U.S. Pat. No. 9,267,745, the entire content of which is incorporated by reference herein. Exemplary commercially available flexible graphite articles that may be used in accordance with the invention of the present disclosure include NEONXGEN® flexible graphite materials, which are available from NeoGraf Solutions, LLC (Lakewood, Ohio). A non-exhaustive list of exemplary grades of NEONXGEN materials that may be used to practice the thermal management systems of the present disclosure may include the N, P, and U series of the NEONXGEN materials, such as N-80, N-100, P-100, N-150, P-150, N-200, P-200, P-250, N-270 and N-300. A range of properties for such materials include: (1) a thickness of 70 microns up to at least 300 microns, such as a thickness of up to 500 microns; (2) an in-plane thermal conductivity (k₁) of 800 W/mK to 1,400 W/mK; (3) a through-plane thermal conductivity (k₁) of 3 W/mK to 6 W/mK; and/or (4) a density of at least 1.8 g/cm³ up to 2.1 g/cm³.

As briefly mentioned, the first element and the optional third element of the thermal management systems of the present disclosure each comprise a flexible graphite article, which may have the same or different physical properties. For example, the first element and the optional third element may comprise flexible graphite articles that have the same or different physical properties including, but not limited to, thickness, in-plane thermal conductivity, and through-plane thermal conductivity.

In embodiments of the present disclosure, the flexible graphite articles have a thickness of at least 65 microns to 500 microns. In embodiments of the present disclosure, the flexible graphite articles have a thickness of at least 65 microns, including from 65 microns to 500 microns, including from 80 microns to 450 microns, from 90 microns to 425 microns, from 100 microns to 400 microns, from 125 microns to 300 microns, and also including from 130 microns to 250 microns. In embodiments of the present disclosure, the flexible graphite articles have a thickness of more than 65 microns to 95 microns, including from 70 microns to 90 microns, and also including from 75 microns to 85 microns. In embodiments of the present disclosure, the flexible graphite articles have a thickness of more than 100 microns, including more than 100 microns to 500 microns, from 110 microns to 400 microns, from 125 microns to 300 microns, and also including from 130 microns to 250 microns. In embodiments of the present disclosure, the flexible graphite articles have a thickness of at least 100 microns, including at least 100 microns to 500 microns, from 110 microns to 400 microns, from 125 microns to 300 microns, and also including from 130 microns to 250 microns.

In embodiments of the present disclosure, the flexible graphite articles have an in-plane thermal conductivity of more than 700 W/mK to 1500 W/mK. In embodiments of the present disclosure, the flexible graphite articles have an in-plane thermal conductivity of more than 700 W/mK, including more than 700 W/mK to 1500 W/mK, from 750 W/mK to 1400 W/mK, from 800 W/mK to 1350 W/mK, from 950 W/mK to 1300 W/mK, and also including from 1000 W/mK to 1200 W/mK. In embodiments of the present disclosure, the flexible graphite articles have an in-plane thermal conductivity of more than 700 W/mK, including more than 700 W/mK to 950 W/mK, from 725 W/mK to 900 W/mK, and also including from 750 W/mK to 850 W/mK. In embodiments of the present disclosure, the flexible graphite articles have an in-plane thermal conductivity of more than 1000 W/mK, including more than 1000 W/mK to 1500 W/mK, from 1025 W/mK to 1400 W/mK, from 1050 W/mK to 1300 W/mK, and also including from 1100 W/mK to 1200 W/mK. In embodiments of the present disclosure, the flexible graphite articles have an in-plane thermal conductivity of at least 1000 W/mK, including at least 1000 W/mK to 1500 W/mK, from 1025 W/mK to 1400 W/mK, from 1050 W/mK to 1300 W/mK, and also including from 1100 W/mK to 1200 W/mK.

In embodiments of the present disclosure, the flexible graphite articles have a through-plane thermal conductivity of less than 6 W/mK, including from 0.5 W/mK to 5.99 W/mK, from 1 W/mK to 5.75 W/mK, from 2 W/mK to 5.5 W/mK, and also including from 3 W/mK to 5 W/mK. In embodiments of the present disclosure, the flexible graphite articles have a through-plane thermal conductivity of no more than 6 W/mK, including from 0.5 W/mK to 6 W/mK, from 1 W/mK to 5.75 W/mK, from 2 W/mK to 5.5 W/mK, and also including from 3 W/mK to 5 W/mK. In embodiments of the present disclosure, the flexible graphite articles have a through-plane thermal conductivity of no more than 4.5 W/mK, including from 0.5 W/mK to 4.5 W/mK, from 0.75 W/mK to 4.25 W/mK, from 1 W/mK to 4 W/mK, from 1.25 W/mK to 3.75 W/mK, from 1.5 W/mK to 3.25 W/mK, and also including from 2 W/mK to 3 W/mK. In embodiments of the present disclosure, the flexible graphite articles preferably have a through-plane thermal conductivity of 3 W/mK to 5 W/mK.

The second element of the thermal management systems in various embodiments of the present disclosure comprises an insulation material having a through-plane thermal conductivity of no more than 0.15 W/mK, including 0.05 W/mK or less, and preferably less than 0.025 W/mK. In certain aspects of the present disclosure, the second element comprises an insulation material having a through-plane thermal conductivity of no more than 0.05 W/mK, including a through-plane thermal conductivity of 0.01 W/mK to 0.049 W/mK, a through-plane thermal conductivity of 0.015 W/mK to 0.049 W/mK, a through-plane thermal conductivity of 0.02 W/mK to 0.049 W/mK, a through-plane thermal conductivity of 0.025 W/mK to 0.049 W/mK, a through-plane thermal conductivity of 0.03 W/mK to 0.049 W/mK, a through-plane thermal conductivity of 0.035 W/mK to 0.049 W/mK, a through-plane thermal conductivity of 0.04 W/mK to 0.049 W/mK, or a through-plane thermal conductivity of 0.045 W/mK to 0.049 W/mK. In certain aspects of the present disclosure, the second element comprises an insulation material having a through-plane thermal conductivity of no more than 0.025 W/mK, including a through-plane thermal conductivity of 0.01 W/mK to 0.025 W/mK, a through-plane thermal conductivity of 0.015 W/mK to 0.025 W/mK, and also including a through-plane thermal conductivity of 0.02 W/mK to 0.025 W/mK.

In embodiments of the present disclosure, the second element has a thickness of less than 2 mm. In embodiments of the present disclosure, the second element may have a thickness of 1 micron to 2 mm, including from 5 microns to 2 mm, from 10 microns to 2 mm, from 20 microns to 2 mm, from 30 microns to 2 mm, from 50 microns to 2 mm, from 70 microns to 2 mm, from 0.1 mm to 1.5 mm, from 0.1 mm to 1 mm, from 0.1 mm to 0.5 mm, from 0.1 mm to 0.3 mm, and also including from 0.1 mm to 0.25 mm. In embodiments of the present disclosure, the second element may have a thickness of 30 microns to 2 mm. In embodiments of the present disclosure, the second element may have a thickness of 1 micron, 5 microns, 10 microns, 20 microns, 30 microns, 50 microns, 70 microns, 100 microns, 150 microns, 200 microns, 250 microns, 500 microns, 750 microns, 1 mm, 1.5 mm, or 2 mm.

In particular embodiments, the thickness of the second element is at least as thick as the thickness of the thickest of the first element and the optional third element. Alternatively, the second element has a thickness that is no more than ten times (10×) the thickness of the thickest of the first element or the optional third element. Preferably, the second element has a thickness that is no more than seven times (7×) the thickness of the thickest of the first element or the optional third element. Further preferably, the thickness of the second element is no more than five times (5×) the thickness of the thickest of the first element or the optional third element. Even further preferred, the second element may have a thickness that is no more than three times (3×) the thickness of the thickest of the first element or the optional third element.

In embodiments of the present disclosure, the insulation material comprises a porous polymer matrix. One example of a suitable porous polymer matrix is an expanded polytetrafluoroethylene (ePTFE) membrane. In embodiments, the ePTFE membrane has a through-plane thermal conductivity of less than 0.15 W/mK, preferably less than 0.05 W/mK, including a through-plane thermal conductivity of 0.025 W/mK to 0.049 W/mK, and also including a through-plane thermal conductivity of 0.03 W/mK to 0.045 W/mK. In embodiments, the ePTFE membrane has a through-plane thermal conductivity of 0.025 W/mK to no more than 0.05 W/mK, including a through-plane thermal conductivity of 0.025 W/mK, 0.03 W/mK, 0.035 W/mK, 0.04 W/mK, 0.045 W/mK, or 0.05 W/mK.

A preferred thickness of the ePTFE membrane is 100 microns or less, including from 1 micron to 100 microns, from 1 micron to 90 microns, from 5 microns to 80 microns, from 10 microns to 75 microns, and also including from 20 microns to 60 microns. In embodiments, the ePTFE membrane may have a thickness of 1 micron to 50 microns, including from 1 micron to 40 microns, and also including from 5 microns to 25 microns. Exemplary commercially available ePTFE membranes that may be used in accordance with the invention of the present disclosure are available from W. L. Gore & Associates, Inc. (Newark, Del.).

An example of a suitable ePTFE membrane may include at least 40% and up to 80% parts by weight of air. A porosity of the ePTFE membrane may range from about 40% to about 97%. A porosity measurement instrument (“PMI”) may be used to measure the porosity. Pore size measurements may be made by the Coulter Porometer™, manufactured by Coulter Electronics, Inc. (Hialeah, Fla.). The Coulter Porometer is an instrument that provides automated measurement of pore size distributions in porous media using the liquid displacement method (described in ASTM Standard E1298-89).

Alternative porous polymer matrix materials suitable for use in accordance with the present disclosure include, but are not limited to, expanded polyethylene membranes, a nanofiber web of one or more of the following polymers: polyethylene (“PE”), polypropylene (“PP”) and polyethylene terephthalate (“PET”), woven or non-woven textiles of one or more of the following polymers: polyethylene (“PE”), polypropylene (“PP”) and polyethylene terephthalate (“PET”) and combinations thereof. The above description of properties regarding ePTFE membrane equally applies to the alternative porous polymer matrix materials. Optionally, the porous polymer matrix material may be coated with an adhesive such as but not limited to acrylic and/or silicone polymers.

In embodiments of the present disclosure, the insulation material comprises aerogel particles and polytetrafluoroethylene (PTFE) and has a through-plane thermal conductivity of less than 0.025 W/mK (at atmospheric conditions, i.e., about 298.15 K and about 101.3 kPa), including a through-plane thermal conductivity of less than or equal to 0.02 W/mK, and also including a through-plane thermal conductivity of less than or equal to 0.017 W/mK. In embodiments of the present disclosure, the insulation material comprises aerogel particles and polytetrafluoroethylene (PTFE) and has a through-plane thermal conductivity of 0.025 W/mK or less (at atmospheric conditions, i.e., about 298.15 K and about 101.3 kPa), including a through-plane thermal conductivity of 0.01 W/mK to 0.025 W/mK, including a through-plane thermal conductivity of 0.015 to 0.025 W/mK, and also including a through-plane thermal conductivity of 0.02 W/mK to 0.025 W/mK. Aerogel particles suitable for use in embodiments of the insulation material of the present invention include both inorganic and organic aerogels, and mixtures thereof. Non-exhaustive exemplary inorganic aerogels may include those formed from, in the alternative, inorganic oxides of silicon, aluminum, titanium, zirconium, hafnium, yttrium, vanadium, and the like, including mixtures thereof, with silica aerogels being particularly preferred. Organic aerogels are also suitable for use in embodiments of the insulation material of the present invention and may be prepared from any of the following: carbon, polyacrylates, polystyrene, polyacrylonitriles, polyurethanes, polyimides, polyfurfuryl alcohol, phenol furfuryl alcohol, melamine formaldehydes, resorcinol formaldehydes, cresol, formaldehyde, polycyanurates, polyamides, such as but not limited to polyacrylamides, epoxides, agar, agarose, and the like. Preferably, the aerogel particles have an average pore diameter of less than 70 nm, including from 1 nm to 70 nm, from 5 nm to 70 nm, and also including from 10 nm to 60 nm.

In addition to aerogel particles, the insulation material according to embodiments of the present disclosure comprise PTFE. The PTFE may function as a binder, wherein the term “binder,” as used herein, means that the PTFE component causes particles of aerogel to be held together or cohere with other aerogel particles, or additional optional components. In embodiments of the present disclosure, the insulation material comprises a mixture of aerogel particles and PTFE particles comprising greater than or equal to about 40 wt % aerogel, greater than or equal to about 60 wt % aerogel, or greater than or equal to about 80 wt % aerogel.

Preferred mixtures of aerogel particles and PTFE particles comprise from about 40 wt % to about 95 wt % aerogel, further from about 40 wt % to about 80 wt % aerogel. PTFE particles comprise preferably less than or equal to about 60 wt % of the aerogel/PTFE mixture, less than or equal to about 40 wt % of the mixture, or less than or equal to about 20 wt % of the aerogel/PTFE mixture.

Preferred mixtures comprise an aerogel/PTFE mixture comprising from about 5 wt % to about 60 wt % PTFE, and from about 20 wt % to about 60 wt % PTFE. Exemplary insulation materials suitable for use in the invention of the present disclosure are described in U.S. Pat. No. 7,118,801, the entire content of which is incorporated by reference herein.

Exemplary commercially available insulation materials that may be used in accordance with the invention of the present disclosure are available from W. L. Gore & Associates, Inc. (Newark, Del.). In preferred embodiments, the aerogel/PTFE insulation article is monolithic. In other embodiments, the aerogel/PTFE insulation article is a homogeneous composite article. In embodiments, the aerogel/PTFE insulation article may be cladded on one or more sides with a porous polymer matrix, such as an ePTFE membrane or one of the alternative porous polymer matrix materials described above. Benefits of the aerogel/PTFE insulation article may include its high strength, high loading and/or high temperature resistance. The aerogel/PTFE insulation article may have the afore improved properties over many other options in terms of raw numbers as well on a basis of per unit volume or thickness. Particular embodiments of the aerogel/PTFE insulation article may have a thickness of 30 microns to 2 mm.

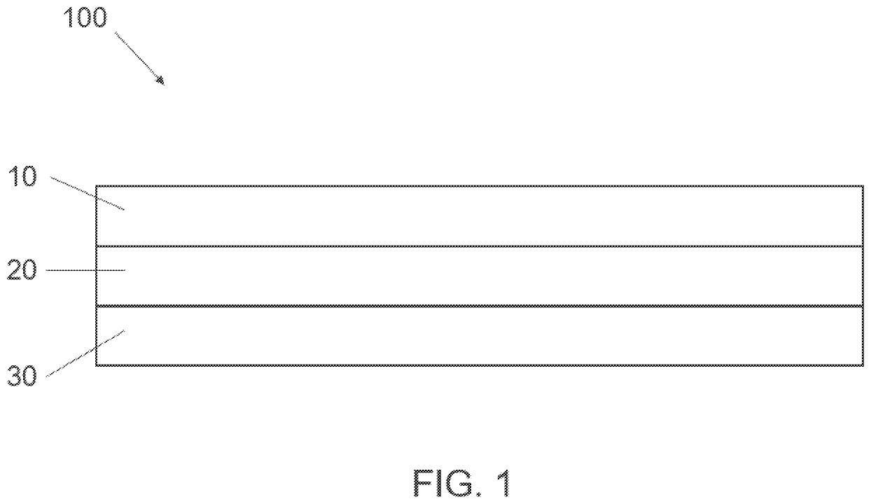

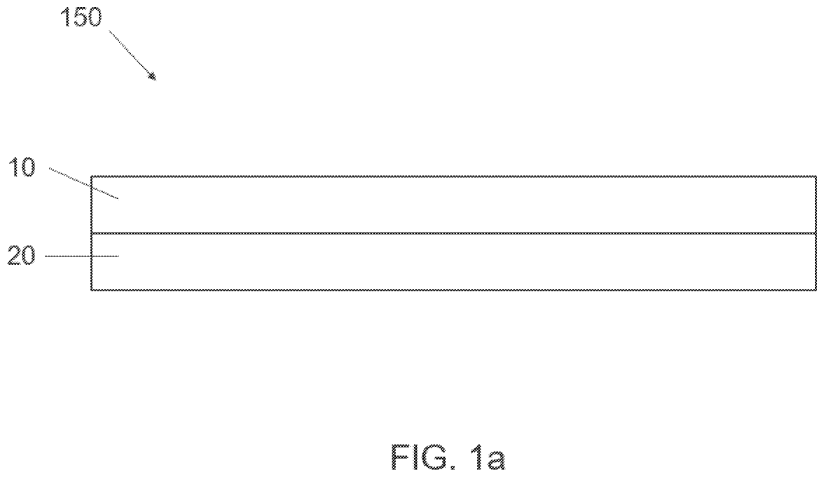

Referring now to FIG. 1, an embodiment of a thermal management system 100 of the present disclosure is illustrated. The thermal management system 100 comprises a first element 10, a second element 20 adjacent to the first element 10, and an optional third element 30 adjacent to the second element 20 and opposed to the first element 10. Accordingly, the thermal management system 100 may have a sandwich-type structure or construction with the second element 20 disposed between the first element 10 and the optional third element 30.

As previously discussed, the first element 10 and the optional third element 30 of the thermal management system 100 each comprise a flexible graphite article, which may have the same or different physical properties, and the second element 20 of the thermal management system 100 comprises an insulation material having a through-plane thermal conductivity of less than 0.05 W/mK, and preferably less than 0.025 W/mK.

In one embodiment, a thermal management system 100 of the present disclosure comprises: a first element 10 comprising a flexible graphite article having a thickness of more than 65 microns to 95 microns, an in-plane thermal conductivity of more than 700 W/mK up to 950 W/mK, and a through-plane thermal conductivity of less than 6 W/mK; a second element 20 adjacent the first element 10, the second element 20 comprising an insulation material having a through-plane thermal conductivity of less than 0.025 W/mK; and an optional third element 30 adjacent the second element 20 and opposed to the first element 10, the optional third element 30 comprising a flexible graphite article having a thickness of at least 65 microns, an in-plane thermal conductivity of more than 700 W/mK, and a through-plane thermal conductivity of less than 6 W/mK.

In a second embodiment, a thermal management system 100 of the present disclosure comprises: a first element 10 comprising a flexible graphite article having a thickness of more than 100 microns and an in-plane thermal conductivity of more than 1000 W/mK; a second element 20 adjacent the first element 10, the second element 20 comprising an insulation material having a through-plane thermal conductivity of less than 0.025 W/mK; and an optional third element 30 adjacent the second element 20 and opposed to the first element 10, the optional third element 30 comprising a flexible graphite article having a thickness of more than 100 microns and an in-plane thermal conductivity of more than 1000 W/mK. In certain embodiments, the thickness of at least one of the first element 10 or the optional third element 30 is at least 125 microns, including at least 130 microns, at least 150 microns, and up to 500 microns, and a thickness of the second element is less than 2 mm, including less than 1 mm, and also including from 0.1 mm to 0.25 mm.

In another embodiment, a thermal management system 100 of the present disclosure comprises: a first element 10 comprising a flexible graphite article having a thickness of at least 100 microns and an in-plane thermal conductivity of more than 1000 W/mK; a second element 20 adjacent the first element 10, the second element 20 comprising an insulation material having a through-plane thermal conductivity of less than 0.025 W/mK; and an optional third element 30 adjacent the second element 20 and opposed to the first element 10, the optional third element 30 comprising a flexible graphite article having a thickness of at least 100 microns and an in-plane thermal conductivity of more than 1000 W/mK. In certain embodiments, the thickness of at least one of the first element 10 or the optional third element 30 is at least 125 microns, including at least 130 microns, at least 150 microns, and up to 500 microns, and a thickness of the second element is less than 2 mm, including less than 1 mm, and also including from 0.1 mm to 0.25 mm.

In a further embodiment, a thermal management system 100 of the present disclosure comprises: a first element 10 comprising a flexible graphite article having a thickness of at least 100 microns and an in-plane thermal conductivity of more than 1000 W/mK; a second element 20 adjacent the first element 10, the second element 20 comprising an insulation material having a through-plane thermal conductivity of less than 0.05 W/mK; and an optional third element 30 adjacent the second element 20 and opposed to the first element 10, the optional third element 30 comprising a flexible graphite article having a thickness of at least 100 microns and an in-plane thermal conductivity of more than 1000 W/mK. In certain embodiments, the thickness of at least one of the first element 10 or the optional third element 30 is at least 125 microns, including at least 130 microns, at least 150 microns, and up to 500 microns, and a thickness of the second element is less than 2 mm, including less than 1 mm, and also including from 0.1 mm to 0.25 mm.

Any of the previously described materials and ranges of properties (e.g., thickness, in-plane thermal conductivity, through-plane thermal conductivity) of the first element 10, second element 20, and optional third element 30 consistent with the disclosed embodiments of the thermal management system 100 may be used.

In embodiments of the present disclosure, at least one of the first element 10 and the optional third element 30 of the thermal management system 100 is monolithic. In embodiments of the present disclosure, both the first element 10 and the optional third element 30 of the thermal management system 100 are monolithic.

In embodiments of the present disclosure, the first element 10 and the optional third element 30 are adhered to opposing surfaces of the second element 20. The first element 10 and the optional third element 30 may be adhered to the second element 20 using a double-sided adhesive tape. Preferably, the double-sided adhesive tape has a thickness of less than 20 microns, including a thickness of less than 15 microns, and also including a thickness of less than 10 microns. The double-sided adhesive tape may comprise an acrylic or latex adhesive material or the like. In embodiments of the present disclosure, the double-sided adhesive tape may include nominal air gaps or pores in the adhesive. In embodiments of the present disclosure, the adhesive material of the double-sided adhesive tape is a non-water based and non-foam based adhesive.

In embodiments of the present disclosure, the thermal management system 100 may comprise an optional coating layer on at least one of the first element 10 and the optional third element 30. In certain embodiments, the coating layer comprises one or more of a dielectric material, a plastic material (e.g., polyethylene, a polyester (polyethylene terephthalate), or a polyimide), and a double-sided adhesive tape having a release liner on the outward facing adhesive material. Preferred double-sided adhesive tapes comprise a carrier (e.g., a resin film) having a thickness of no more than 10 microns.

Referring now to FIG. 1a, another embodiment of a thermal management system 150 according to the present disclosure is illustrated. The thermal management system 150 may comprise a first element 10 comprising a flexible graphite article having a thickness of more than 100 microns and an in-plane thermal conductivity of more than 1,000 W/mK. For applications in an electronic device, the flexible graphite article may preferably be in the form of a sheet.

With continued reference to FIG. 1a, the thermal management system 150 also comprises a second element 20 comprising an insulation material having a through-plane thermal conductivity of less than 0.05 W/mK. A thickness of the second element 20 comprises at least the same thickness as the thickness of the first element 10 and may be up to no more than ten times (10×) the thickness of the first element 10, including no more than seven times (7×) the thickness of the first element 10, no more than five times (5×) the thickness of the first element 10, and also including no more than three times (3×) the thickness of the first element 10. Non-limiting examples of suitable materials for the second element 20 include an aerogel-based material, as described herein, or porous polymer matrix such as but not limited to an expanded polytetrafluoroethylene (ePTFE) membrane.

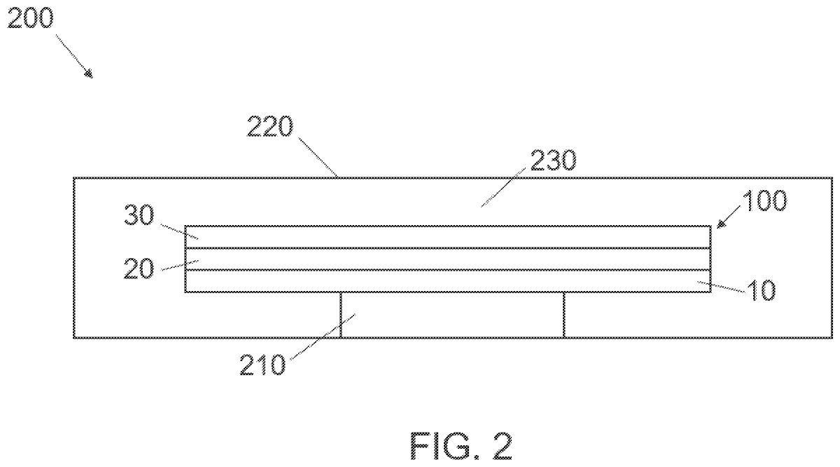

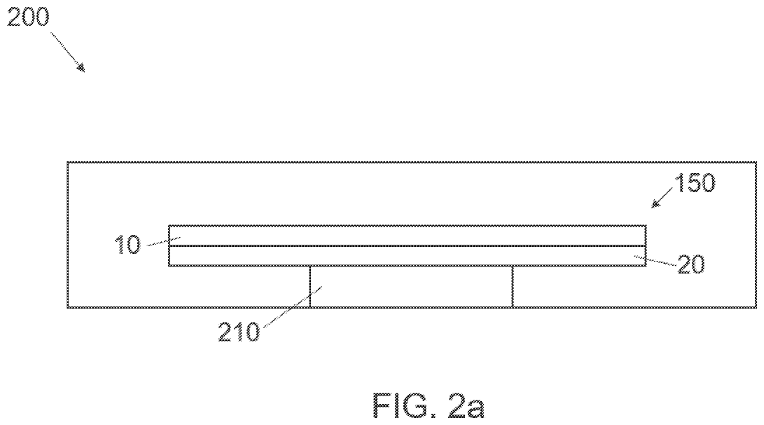

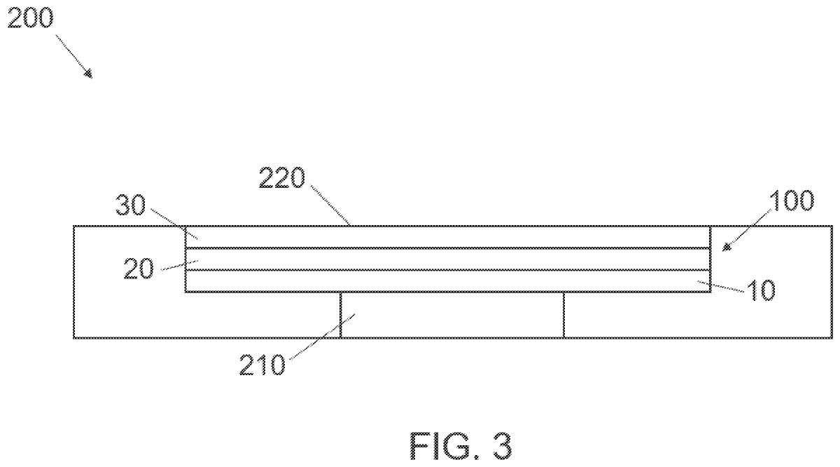

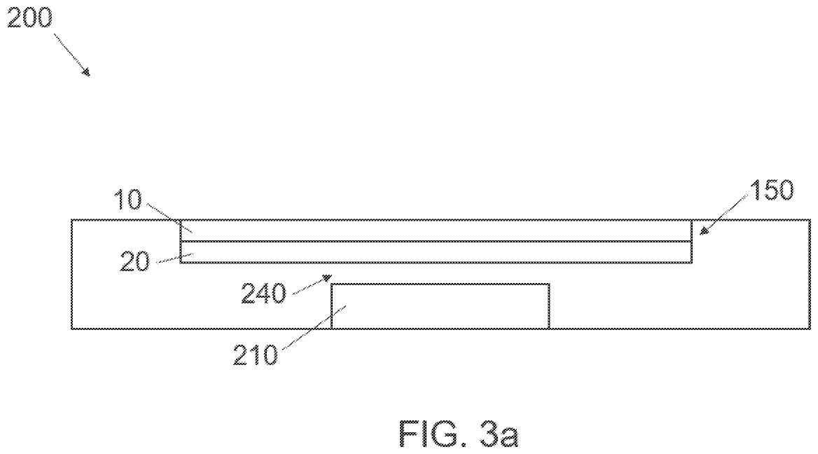

When this embodiment is incorporated into an electronic device 200, the thermal management system 150 is in operative thermal communication with a heat source 210 (i.e., electronic component as described herein) and second element 20 of the thermal management system 150 is aligned adjacent heat source 210, as shown in FIG. 2a. Optionally, heat source 210 and the thermal management system 150 may be spaced apart from each other, as illustrated in FIG. 3a. An air gap 240 may be located between heat source 210 and second element 20 of the thermal management system 150.

Turning to specific examples of thickness, the thickness of the first element 10 for this embodiment of the thermal management system 150 may range from 100 microns to 500 microns. Likewise, the thickness of the second element 20 may range from 100 microns up to about 5 mm. Other examples of a suitable thickness of the second element 20 comprise any of the following: 1.1, 1.25, 1.5, 1.75, 2, 2.25, 2.5, 3, 3.5, 4, 5, 6, 7, 8, 9, or 10 times the thickness of first element 10.

Referring now to FIG. 2, an embodiment of an electronic device 200 including a thermal management system 100 of the present disclosure is illustrated. The electronic device 200 comprises a heat source 210, an external surface 220, and a thermal management system 100. Either the first element 10 or the optional third element 30 of the thermal management system 100 is in operative thermal communication with the heat source 210, and the other of the first element 10 and the optional third element 30 faces the external surface 220. As seen in FIG. 2, the electronic device 200 is illustrated with the first element 10 of the thermal management system 100 in operative thermal communication with the heat source 210 and the optional third element 30 of the thermal management system 100 facing the external surface 220.

As used herein, two materials are in operative thermal communication when heat can be conducted from one to the other through the communication of kinetic energy from particle to particle with no net displacement of the particles. Operative thermal communication may include embodiments in which the thermal management system 100, 150 is in physical contact with the heat source 210 as well as embodiments when there is an air gap between the thermal management system 100, 150 and the adjacent surface of heat source 210 (i.e., thermal management system 100, 150 and heat source 210 are spaced apart). Likewise regarding the exterior surface of the thermal management system 100, 150, embodiments disclosed herein may include the exterior surface of thermal management system 100, 150 being in physical contact with external surface 220 of electronic device 200 or the external facing surface of the thermal management system 100, 150 being spaced apart from external surface 220 of electronic device 200 (i.e., an air gap is between the thermal management system 100, 150 and external surface 220). Functionally, operative thermal communication will include at least a measurable amount of heat that is transferred from a first body to a second body, such that the temperature of the second body increases. The increase in temperature of the second body is measurable.

The thermal management systems 100, 150 of the present disclosure are used to effectively manage the heat generated by a heat source 210 of an electronic device 200 to reduce or eliminate hot spots on an external surface 220 of the electronic device 200. The term “hot spot” generally refers to an area having a higher temperature than surrounding areas. The thermal management systems 100, 150 of the present disclosure dissipate and/or spread the heat generated by the heat source 210 more evenly across the electronic device 200 to reduce or eliminate hot spots. The thermal management systems 100, 150 used in the electronic device 200 may be any one of the thermal management systems 100, 150 described herein. Non-limiting examples of electronic devices 200 of the present disclosure include smartphones, tablets, and laptops.

Embodiments of the present disclosure include the thermal management system 100, 150 arranged in the electronic device 200 such that an air gap 230 is between the external surface 220 and the element of the thermal management system 100, 150 facing (or proximate) the external surface 220. As seen in FIG. 2, the air gap 230 is defined by the distance between the external surface 220 and a surface of the optional third element 30 of the thermal management system 100 facing external surface 220.

Embodiments of the present disclosure also include the electronic device 200 and the thermal management system 100, 150 configured such that a portion of the external surface 220 is in physical contact with the element of the thermal management system 100, 150 facing the external surface 220. In embodiments of the present disclosure, the external surface 220 may comprise a case or housing of the electronic device 200. As seen in FIG. 3, a portion of the external surface 220 of the electronic device 200 is in physical contact with the optional third element 30 of the thermal management system 100. In other embodiments of the present disclosure, the portion of the external surface 220 in physical contact with the element of the thermal management system 100, 150 has the same surface area of the element of the thermal management system 100, 150 facing the external surface 220, and optionally the portion of the external surface 220 in physical contact with the element of the thermal management system 100, 150 is devoid of an offset such that no air gap is created.

Referring to FIGS. 2 and 3, in embodiments of the electronic device 200 of the present disclosure, a surface area of the element of the thermal management system 100 in operative thermal communication with the heat source 210 (in this case, the first element 10) is greater than a surface area of the portion of the heat source 210 which is in operative thermal communication with the element 10. Such embodiments increase the effective surface area of the heat source 210 to facilitate heat dissipation and spreading, thereby reducing or eliminating hot spots. In some embodiments, the surface area of the element of the thermal management system 100 in operative thermal communication with the heat source 210 is at least 1.5 times greater than (e.g., 1.5 times greater than to 5 times greater than) a surface area of the portion of the heat source 210 which is in operative thermal communication with the element of the thermal management system 100.

In embodiments of the present disclosure, the heat source 210 can be an electronic component. The electronic component can comprise any component that produces sufficient heat to generate hot spots or interfere with the operation of the electronic component, or the electronic device 200 of which electronic component is an element, if not dissipated. In embodiments of the present disclosure, the heat source 210 can comprise a microprocessor or computer chip, an integrated circuit, control electronics for an optical device like a laser or a field-effect transistor (FET), rectifier, inverter, converter, variable speed drive, insulated gate bipolar transistor, thyristor, amplifier, inductors, capacitors or components thereof, or other like electronic elements. In other examples, the heat source 210 can be a wireless charging component, such as for example, an induction coil.

Embodiments of the thermal management systems disclosed herein have application to electronic devices with power specifications of up to at least about 100 watts (W). Typical power specifications for consumer electronics may range from about 2 W or 3 W to about 100 W, from about 2 W to about 100 W, from about 10 W to about 50 W, from about 50 W to about 100 W, and also including from about 2 W to about 10 W.

In certain embodiments, a power of the heat source 210 is no more than 10 W. In certain embodiments, a power of the heat source 210 is no more than 5 W. In certain embodiments, a power of the heat source 210 is less than 1 W, including from 0.1 W to 0.95 W, from 0.1 W to 0.75 W, and also including from 0.1 W to 0.5 W. In certain embodiments, a power of the heat source 210 is less than 1 W up to 10 W, including from 0.1 W to 10 W, from 0.25 W to 9 W, and also including from 0.5 W to 5 W.

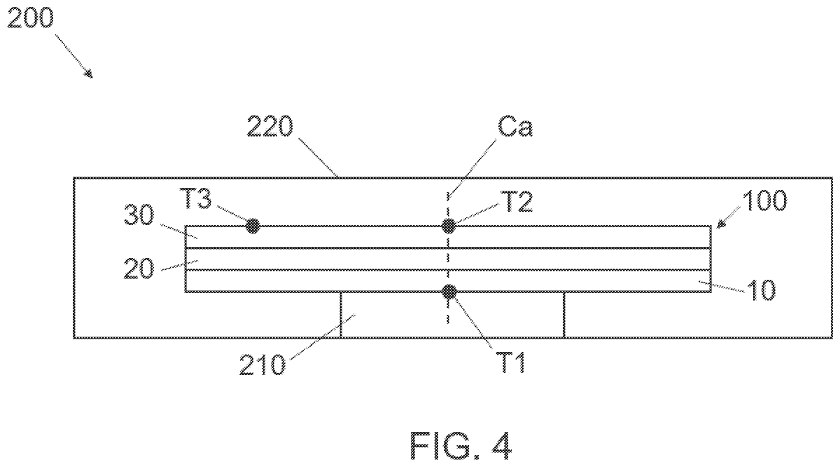

Referring now to FIG. 4, a schematic representation of an embodiment of an electronic device 200 of the present disclosure is shown. As seen in FIG. 4, the first element 10 of the thermal management system 100 is in operative thermal communication with the heat source 210, and the optional third element 30 of the thermal management system 100 faces the external surface 220 of the electronic device. As seen in FIG. 4, point T1 refers to a temperature at a point on a surface of the first element 10 of the thermal management system 100 that is in operative thermal communication with the heat source 210. Point T1 may also be referred to as a junction temperature. As used in conjunction with the embodiment shown in FIG. 4, the term “hot spot” refers to that portion of an element of the thermal management system 100 that is aligned (typically vertically aligned) with the heat source 210. A user interface hot spot on an external surface 220 of the electronic device 200 will typically coincide with the position of the hot spot of the thermal management system 100. Also illustrated in FIG. 4, is point T2, which refers to a temperature at a point on a surface of the optional third element 30 of the thermal management system 100 that is in alignment with the heat source 210 and facing the external surface 220 of the electronic device 200, and point T3, which refers to a temperature on a point of the surface of the optional third element 30 of the thermal management system 100 facing the external surface 220 of the electronic device 200 that is separated by a distance from point T2. As point T2 is aligned with the heat source 210, point T2 may be considered a hot spot. The distance between point T3 and point T2 is measured in the x-y plane and may be a radius extending from point T2 in the x-y plane.

In embodiments of the present disclosure, a temperature differential between point T2 and point T3 is less than 2.5° C., when point T2 and point T3 are separated by a distance of up to 100 mm. In embodiments of the present disclosure, a temperature differential between point T2 and point T3 is less than 2° C., when point T2 and point T3 are separated by a distance of up to 100 mm. In embodiments of the present disclosure, a temperature differential between point T2 and point T3 is less than 2.5° C., when point T2 and point T3 are separated by a distance of 60 mm to 100 mm, including from of 60 mm to 95 mm, from of 70 mm to 90 mm, and also including 80 mm. In embodiments of the present disclosure, a temperature differential between point T2 and point T3 is less than 2° C., when point T2 and point T3 are separated by a distance of 60 mm to 100 mm, including from of 60 mm to 95 mm, from of 70 mm to 90 mm, and also including 80 mm. In embodiments of the present disclosure, a temperature differential between point T2 and point T3 is less than 2.5° C., when point T2 and point T3 are separated by a distance of up to 50 mm. In embodiments of the present disclosure, a temperature differential between point T2 and point T3 is less than 2° C., when point T2 and point T3 are separated by a distance of up to 50 mm. In embodiments of the present disclosure, a temperature differential between point T2 and point T3 is less than 2.5° C., when point T2 and point T3 are separated by a distance of 35 mm to 50 mm. In embodiments of the present disclosure, a temperature differential between point T2 and point T3 is less than 2° C., when point T2 and point T3 are separated by a distance of 35 mm to 50 mm.

Referring again to FIG. 4, point T1 and point T2 lie along a common axis Ca of the thermal management system 100. In embodiments of the present disclosure, a temperature differential between point T1 and point T2 is more than 1.5° C. In embodiments of the present disclosure, a temperature differential between point T1 and point T2 is at least 2° C. In embodiments of the present disclosure, a temperature differential between point T1 and point T2 is more than 2° C. In embodiments of the present disclosure, a temperature differential between point T1 and point T2 is at least 3° C. In embodiments of the present disclosure, a temperature differential between point T1 and point T2 is from 1.5° C. to 6° C., including from 1.5° C. to 5° C., and also including from 2° C. to 4° C.

Further considering the embodiments disclosed herein, the junction temperature (Ta) is the temperature of the heat source at the junction between the heat source and the thermal management system and the skin temperature (Tₛₖ) is the temperature on the external surface of the device. The delta (Δ) between Tⱼ and Tₛₖ may be as large as 60° C., with a typical range from 10° C. to 30° C. Referring to FIG. 4, in the case of a larger Δ, such embodiments may also have a larger differential between T2 and T3. Examples of a larger differential between T2 and T3 may range from 10° C. to 20° C.

In practice, the use of the thermal management systems of the present disclosure has various options to consider regarding the orientation of the thermal management system within any particular electronic device. The options may be exclusive or inclusive of each other depending on the device, but such options are applicable to all embodiments disclosed herein. The options are:
a. a space (e.g., air gap) between the heat source and the thermal management system;
b. a space (e.g., air gap) between the thermal management system and the external surface of the electronic device;
c. a space (e.g., air gap) between both the heat source and the thermal management system and the thermal management system and the external surface of the electronic device (e.g., an offset); and/or
d. the thermal management system may include a space (e.g., air gap), for example a portion of the thermal management system may be in contact with the heat source and another portion of the thermal management system may be in contact with the external surface of the electronic device.

For those embodiments which include a space, the space will form a surface for natural convection heat dissipation.

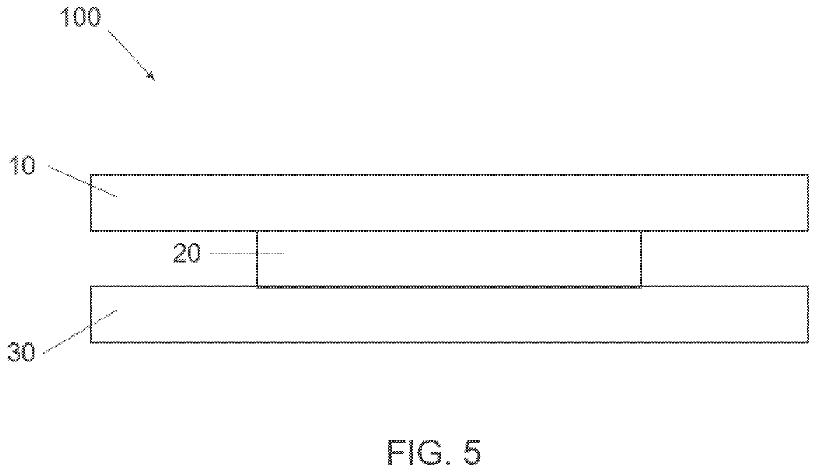

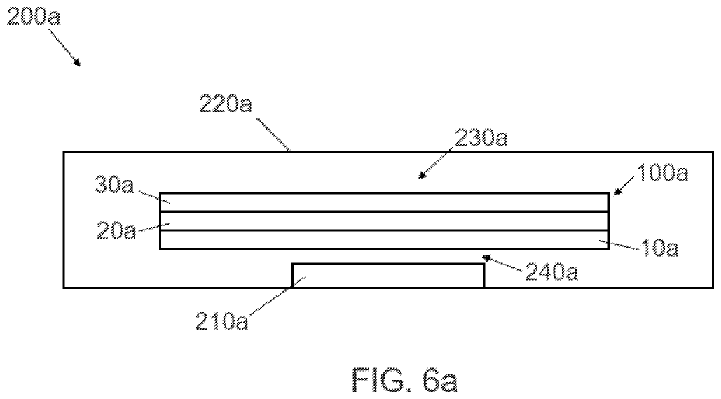

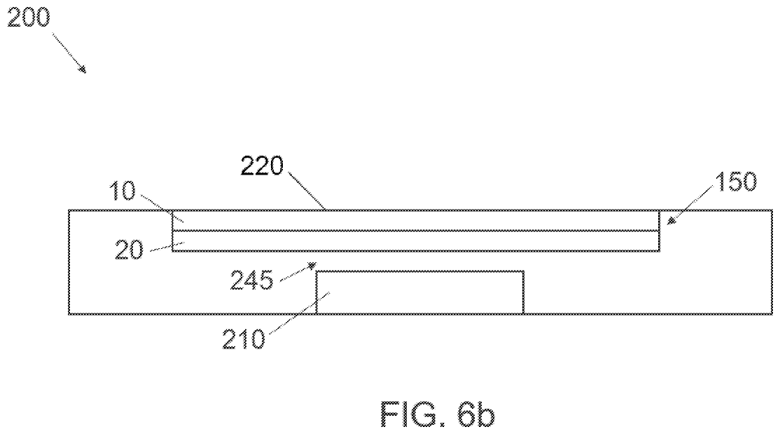

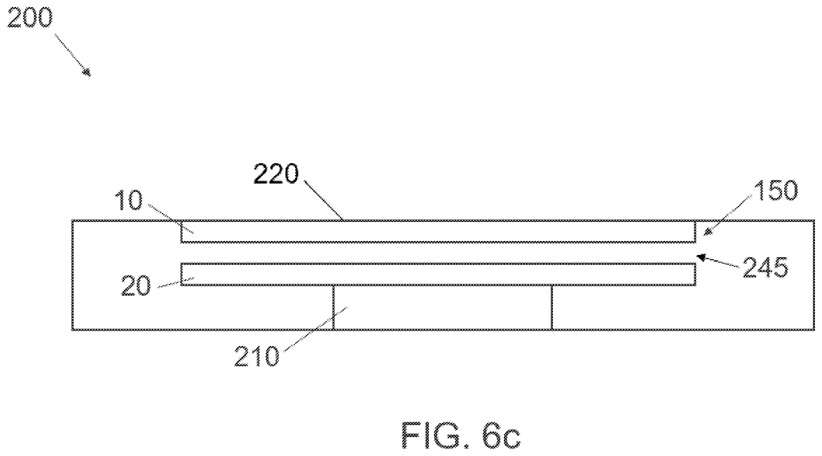

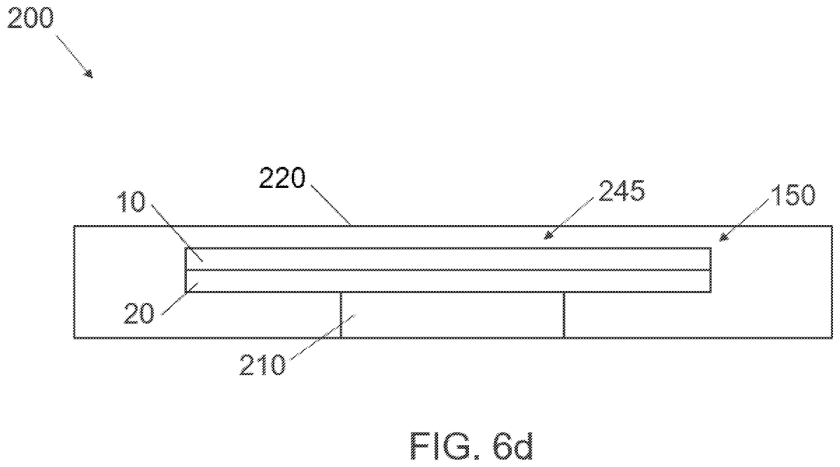

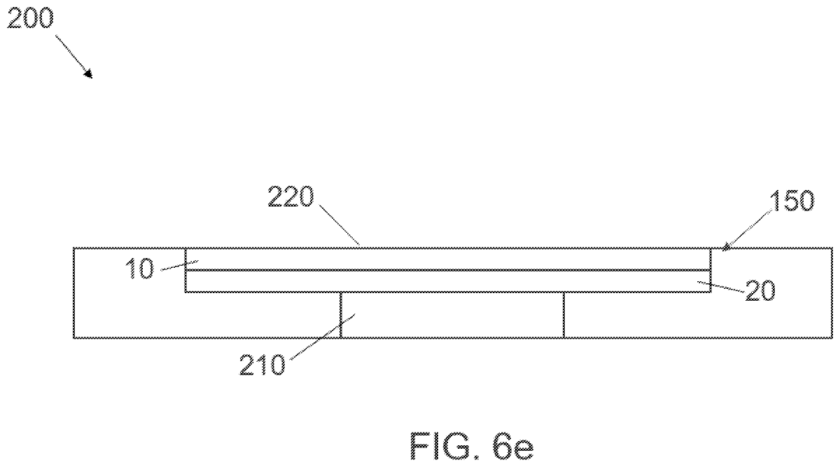

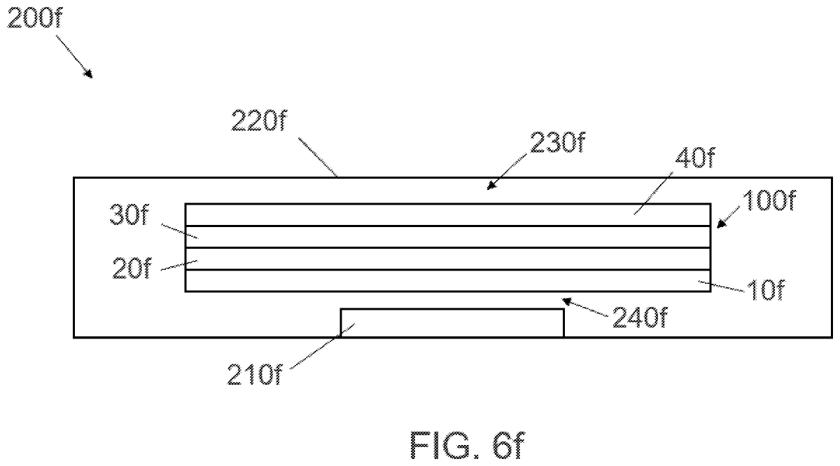

Another optional consideration is that the first element 10 and third element 30 (i.e., flexible graphite article) and the second element 20 (i.e., insulation material) of the thermal management system 100 are not required to have the same thermal communication surface area. An example of such a configuration is illustrated in FIG. 5, where the second element 20 has a smaller thermal communication surface area than the thermal communication surface areas of the first element 10 and the third element 30. The concept illustrated in FIG. 5 is also applicable to the embodiments illustrated in FIGS. 1-4 as well as those of FIGS. 6a-6f.

Preferably, the insulation will have a thermal communication surface area that is at least equal to a thermal communication surface area of the heat source. Preferably, the flexible graphite will have a larger thermal communication surface area than the thermal communication surface area of the heat source. Examples of ratios of the thermal communication surface area of the flexible graphite to the thermal communication surface area of the heat source are at least 1.1:1, 1.25:1, 1.5:1, 2:1, 3:1, 4:1, 5:1, 10:1, 20:1, 30:1, 40:1, 50:1, 60:1, 70:1, 80:1, 90:1, and up to 100:1. In the case that the insulation has a larger thermal communication surface area than the heat source, the same ratios may apply. For particular electronic devices and particular models, the ratio of the thermal communication surface area of the flexible graphite (or the insulation) to the thermal communication surface area of the heat source may be as high as about 100:1 or less, or about 50:1 or less. For a cell phone (also known as a “smart phone”) the ratio of the thermal communication surface area of the flexible graphite (or the insulation) to the thermal communication surface area of the heat source may be as high as about 30:1 or less or about 15:1 or less.

Also, the thermal management system may be aligned symmetrical with the heat source, or one or more components of the thermal management system may be asymmetric with the heat source. Though not shown, all components of the thermal management system may be aligned asymmetric with the heat source. The concepts disclosed in this paragraph are equally applicable to the insulation material of the thermal management system being in adjacent operative thermal communication with the heat source instead of the flexible graphite article.

Various other embodiments of a device 200a-f including the thermal management system under consideration are illustrated in FIGS. 6a-6f. The thermal management system 100a illustrated in FIG. 6a has a construction that is opposite to the thermal management system 100 illustrated in FIG. 1. Namely, instead of the first element and the optional third element being constructed from one or more of the previously described flexible graphite articles, the first element 10a and the optional third element 30a are constructed from one or more of the previously described insulation materials. In the embodiment shown in FIG. 6a, the first element 10a and the optional third element 30a may be constructed from the same or different insulation materials, as described herein. The second element 20a in FIG. 6a may be any one of the aforementioned flexible graphite materials. Lastly, as shown there is a first space 230a between the device casing 220a and the thermal management system 100a, and there is a second space 240a between the heat source 210a and the thermal management system 100a. However, in alternative embodiments to FIG. 6a, the thermal management system may be adhered to the heat source instead of the device casing, such that a space exists between the thermal management system and the device casing; or a space exists between adjacent elements of the thermal management system.

FIG. 6f is similar to the embodiment of the thermal management systems shown in FIG. 1 as well as in FIG. 6a, except that the thermal management system 100f may include at least one additional element 40f of either the flexible graphite article or the insulation material or both. The embodiment shown includes four elements 10f, 20f, 30f, 40f; such embodiment may include as many elements as desired, as long as it is more than three. Thus, further layers than illustrated are contemplated in this embodiment as well as other embodiments disclosed herein. Likewise, the concept of the embodiment shown in FIG. 6f may include either the flexible graphite article or the insulation material adjacent the heat source 210f. A space 240f may (as shown) or may not be present between the heat source 210f and the thermal management system 100f. Further, a space 230f may (as shown (typically includes an offset not shown)) or may not be present between the thermal management system 100f and the device casing 220f.

FIGS. 6b-6e illustrate devices 200 having various configurations of the two element thermal management system 150 embodiment. As illustrated, the insulation material 20 is adjacent the heat source 210 and the flexible graphite article 10 is adjacent the device casing. These embodiments are equally applicable to the thermal management systems in which the flexible graphite article is adjacent the heat source and the insulation material is adjacent the device casing. Additionally, the various embodiments may include a space or may not. In embodiments which include a space 245, the space 245 may be at any one of the locations shown: (i) adjacent the heat source 210, as shown in FIG. 6b; (ii) between the elements 10, 20 of the thermal management system 150, as shown in FIG. 6c; or (iii) adjacent the device casing 220, as shown in FIG. 6d. As seen in FIG. 6e, there may be no space between the thermal management system 150, the heat source 210, or the device casing. In an embodiment not shown, the two element embodiment (i.e., a flexible graphite article and an insulation material) may include two spaces. One of the spaces will be adjacent the device casing and the other space may be either between the elements of the thermal management system or adjacent the heat source.

The aforenoted flexible graphite articles and insulation materials are equally applicable to the embodiments discussed regarding FIGS. 6a-6f.

The following examples describe various embodiments of the present disclosure. The examples are presented to further illustrate the present invention and are not intended to limit the present invention in any way.

### EXAMPLES

### Example I

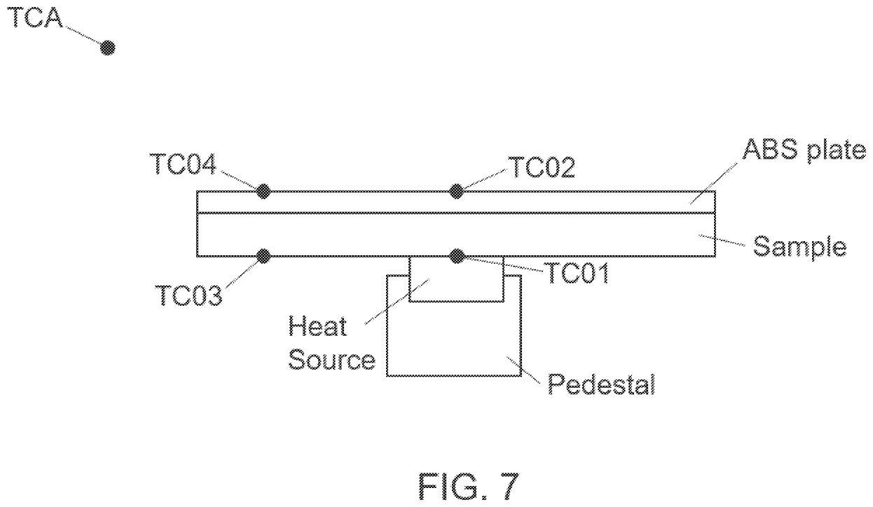

Embodiments of thermal management systems of the present disclosure were prepared and tested for their effectiveness in reducing a hot spot or touch temperature as compared to other thermal management devices. The experimental setup for this example is illustrated in FIG. 7. Briefly, each sample was mounted on a 1 mm thick acrylonitrile butadiene styrene (ABS) for support and suspended in still air atop a pedestal having a calibrated heat source (at 0.5 W). Temperature sensors were used to measure the temperature at points TC01, TC02, TC03, and TC04. A temperature sensor (TCA) was also used to measure the ambient temperature. Points TC01 and TC02 correspond to hot spots as described herein. Point TC03 was spaced from point TC01 by a distance of 50 mm. Similarly, point TC04 was spaced from point TC02 by a distance of 50 mm.

Samples 1 through 4 exemplify thermal management systems of the present disclosure, whereas Samples 5 and 6 are comparative thermal management devices.

Sample 1 included two flexible graphite articles, each having a thickness of about 150 microns, an in-plane thermal conductivity of about 1100 W/mK, and a through-plane thermal conductivity of about 4.5 W/mK. Sandwiched between the two flexible graphite articles was an insulation material having a through-plane thermal conductivity of less than 0.025 W/mK and a thickness of about 250 microns. The total thickness of the thermal management system of Sample 1 was about 550 microns.

Sample 2 included two flexible graphite articles, each having a thickness of about 100 microns, an in-plane thermal conductivity of about 1100 W/mK, and a through-plane thermal conductivity of about 4.5 W/mK. Sandwiched between the two flexible graphite articles was an insulation material having a through-plane thermal conductivity of less than 0.025 W/mK and a thickness of about 100 microns. The total thickness of the thermal management system of Sample 2 was about 300 microns.

Sample 3 included a flexible graphite article having a thickness of about 150 microns, an in-plane thermal conductivity of about 1100 W/mK, and a through-plane thermal conductivity of about 4.5 W/mK. The flexible graphite article was laminated to an insulation material having a through-plane thermal conductivity of less than 0.025 W/mK and a thickness of about 250 microns. The total thickness of the thermal management device of Sample 3 was about 400 microns.

Sample 4 included a flexible graphite article having a thickness of about 100 microns, an in-plane thermal conductivity of about 1100 W/mK, and a through-plane thermal conductivity of about 4.5 W/mK. The flexible graphite article was laminated to an insulation material having a through-plane thermal conductivity of less than 0.025 W/mK and a thickness of about 100 microns. The total thickness of the thermal management device of Sample 4 was about 200 microns.

Sample 5 consisted of a flexible graphite article having a thickness of about 150 microns, an in-plane thermal conductivity of about 1100 W/mK, and a through-plane thermal conductivity of about 4.5 W/mK.

Sample 6 consisted of a flexible graphite article having a thickness of about 100 microns, an in-plane thermal conductivity of about 1100 W/mK, and a through-plane thermal conductivity of about 4.5 W/mK.

In conducting the tests, the heat source was allowed to achieve a steady state. After steady state was achieved, the various temperatures (i.e., ambient, TC01, TC02, TC03, and TC04) experienced by each sample was measured and recorded. To remove variations due to external temperatures, the temperature data for TC01, TC02, TC03, and TC04 was reported as the temperature increase above ambient temperature. For example, the temperature reported for TC02 was the temperature measured at point TC02 minus the measured ambient temperature.

The temperature difference between TC01 and TC02 (i.e., TC01-TC02 value) demonstrates the effectiveness at which the sample can reduce a hot spot. The temperature difference between TC02 and TC04 (i.e., TC02-TC04 value) demonstrates the effectiveness at which the sample can spread heat. The temperature data collected for Samples 1-6 is shown in Table 1 below.

TABLE 1
Temperature Data

| | | | | | TC01- | TC02- |
|---|---|---|---|---|---|---|
| | TC01 | TC02 | TC03 | TC04 | TC02 | TC04 |
| Sample | (° C.) | (° C.) | (° C.) | (° C.) | (° C.) | (° C.) |
| Sample 1 | 11.523 | 7.478 | 7.758 | 6.873 | 4.0 | 0.605 |
| Sample 2 | 10.977 | 7.322 | 6.148 | 6 | 3.7 | 1.322 |
| Sample 3 | 9.511 | 8.242 | 6.121 | 5.239 | 1.3 | 3.003 |
| Sample 4 | 11.892 | 11.099 | 6.737 | 6.259 | 0.8 | 4.840 |
| Sample 5 | 9.813 | 9.127 | 6.182 | 5.937 | 0.7 | 3.190 |
| Sample 6 | 11.072 | 10.853 | 6.559 | 6.308 | 0.2 | 4.545 |

As can be appreciated by the data in Table 1, Samples 1 and 2 were the most effective samples for reducing hot spots. Sample 1 had the highest TC01-TC02 value at about 4° C., and Sample 2 had the next highest TC01-TC02 value at about 3.7° C. Along those same lines, Samples 1 and 2 exhibited the lowest TC02 values (corresponding to a hot spot or touch temperature) at about 7.5° C. and about 7.3° C., respectively. On the other hand, Sample 6 exhibited TC01-TC02 values of less than about 0.5° C., which was reported as 0.2° C., which is at least ten (10) and up to twenty (20) times less than the hot spot reduction achieved by Samples 1 and 2 according to the present disclosure.

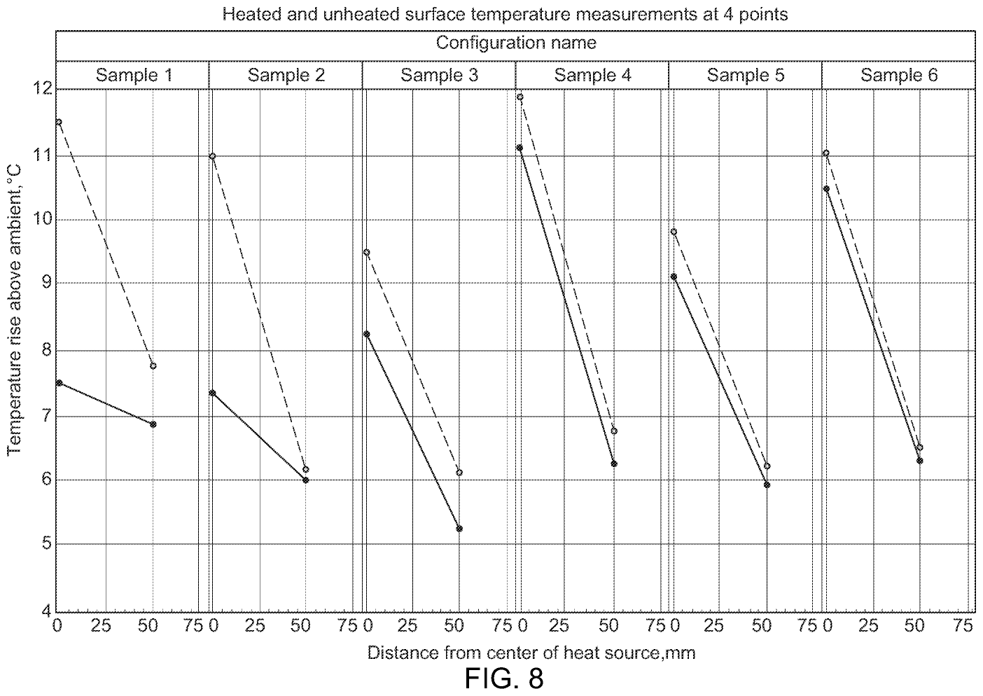

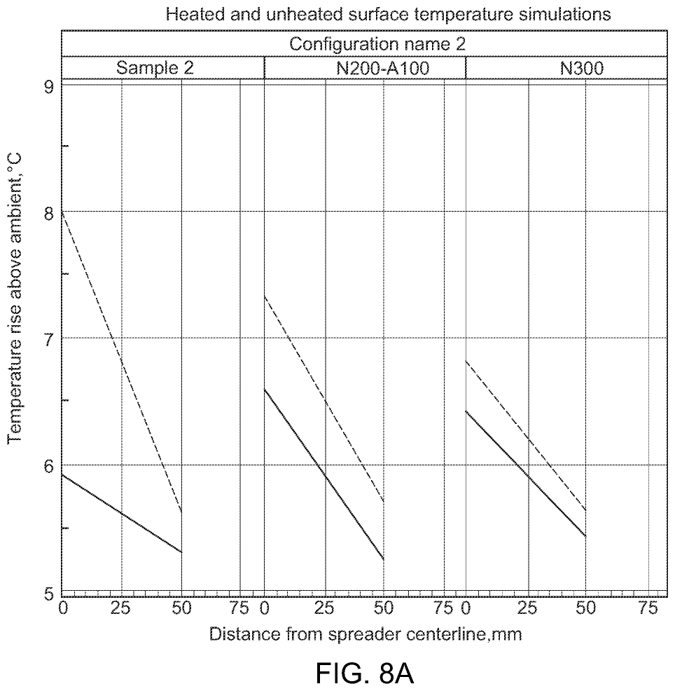

FIG. 8 is presented in furtherance of the data shown in Table 1 above. As illustrated in FIG. 8, the claimed embodiments exhibited the greatest temperature differential between TC01 and TC02 as well as the most uniform temperature between TC02 and TC04 as described above.

Also simulation results for the above data directionally matched the above actual data presented above. To confirm the significance of the Samples 1 and 2 above, a simulation of the same thickness of thermal management system was run for Sample 2 as well as a comparative samples of 1) all flexible graphite article (labeled as N-300) and 2) two-thirds flexible graphite article and one-third insulation material with the flexible graphite article adjacent the external surface (labeled as N200-A100). As stated, all simulations used a sample thickness of 300 microns. The simulation results confirmed that the sandwich constructions of Samples 1 and 2 are the best for lowering skin temperature, as shown in FIG. 8a.

### Example II—Google Pixel 3XL 3DMark Stress Test

In this example the second element of the thermal management system comprises a GORE Thermal Insulation from W. L. Gore & Associates, Inc. (Newark, Del.) as an insulating material (“the insulation”) exhibiting ultra-low thermal conductivity, below that of air, in thin sheet form (100 μm and 250 μm). The NEONXGEN flexible graphite from NeoGraf Solutions, LLC (Lakewood, Ohio) having an ultra-high intrinsic heat spreading capacity (“high-performance thick graphite”) in thick foil form (70 μm to 270 μm) was used.

The insulation is characterized by its distinctively low thermal conductivity, less than 0.020 W/mK. Preferably, the insulating material has an average pore diameter that is smaller than the mean free path of air (approximately 70 nm), for example, less than 70 nm.

An off-the-shelf Google Pixel 3XL (“Pixel”) smartphone was purchased and modified to allow for constant power stressing without thermal throttling. UL's 3DMark −Slingshot Extreme was chosen for testing as it is a widely-accepted benchmark used to score the physics (CPU) and graphics (GPU) of high-end smartphones. In order to achieve steady-state test results, the Professional Version of 3DMark was purchased and installed on the Pixel to enable infinite looping of the 90-second Slingshot Extreme benchmark test. All testing was conducted in a still air environment with tightly controlled ambient temperature and humidity. Parameters available for measuring include surface point temperatures via thermocouples, images via IR camera (Fluke, Model Ti55), internal component temperatures (CPU, GPU, etc.) via built-in thermistors, CPU and GPU clock frequencies, and system performance via Slingshot Extreme benchmark score.

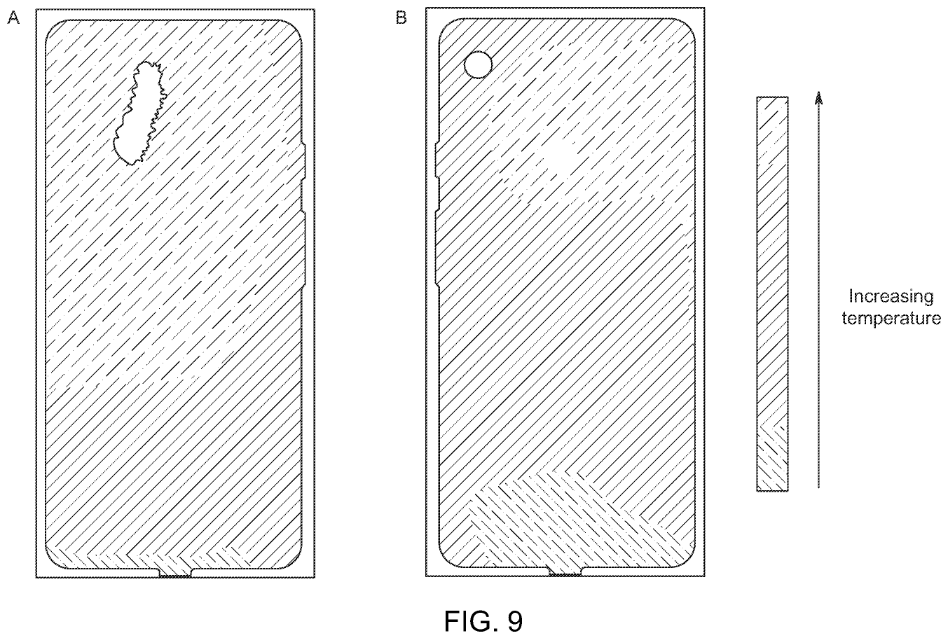

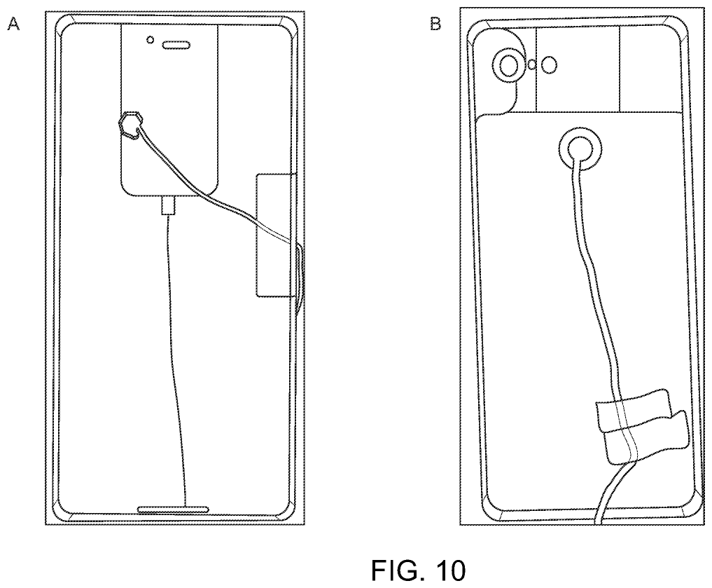

An initial stress test was run in the out-of-box condition with IR imaging (FIG. 9). Hot spot locations were identified and chosen for placement of thermocouples via TIMs (FIG. 10).

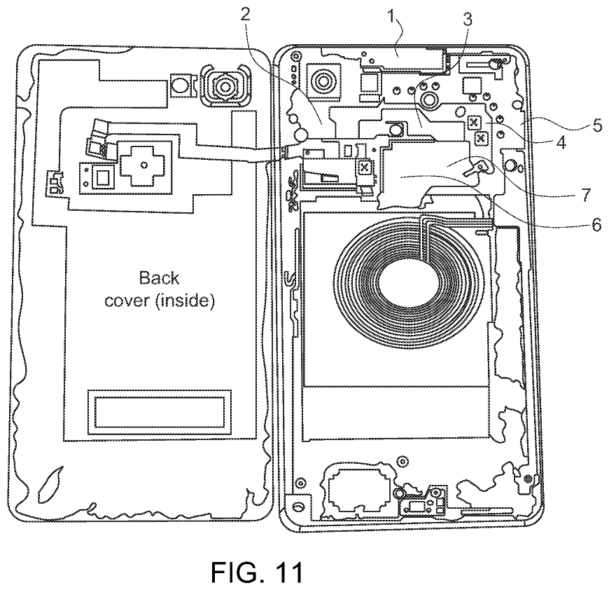

The Pixel back cover was removed by means of heating and breaking adhesive. A conformable polymer was placed inside the back cover at seven different locations near the system on chip (“SoC”) (FIG. 11) to determine the space available for a thermal management system; the back cover was then replaced to compress the polymer into the existing air gap at each location. The back cover was removed again and thickness at all locations was measured via snap gauge on the compressed polymer. This process was repeated twice (2×) more and all thickness measurements per location were averaged. Thickness means are detailed in Table 2.

TABLE 2
Air Gap Measurements Near SoC in Closed Pixel Device

| Location | Mean Gap Measurement (mm) |
|---|---|
| 1 | 0.900 |
| 2 | 0.625 |
| 3 | 0.520 |
| 4 | 0.520 |
| 5 | 0.440 |
| 6 | 0.450 |
| 7 | 0.640 |

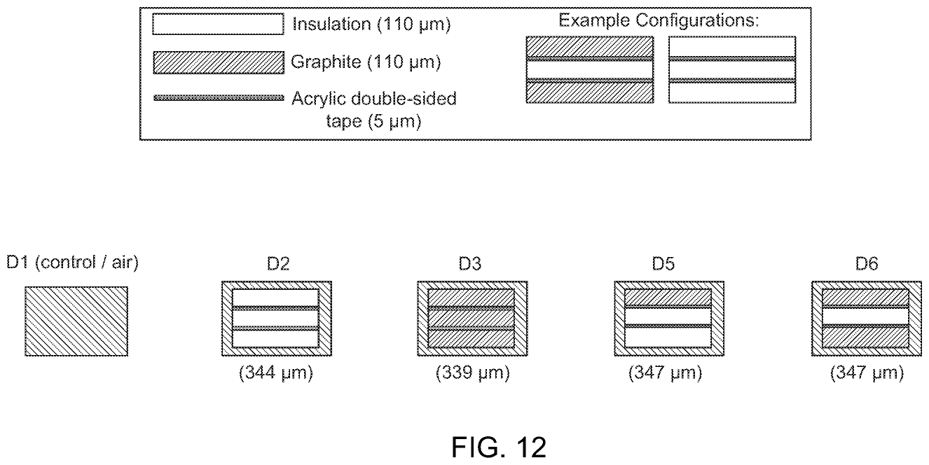

In order to avoid mechanical compression in locations 5 and 6, a nominal thickness of 350 μm was chosen for all thermal management systems. Physical materials for testing included 110 μm insulation sheets, 110 μm graphite foils and 5 μm acrylic double-sided tape. Materials and example configurations are depicted in FIG. 12.

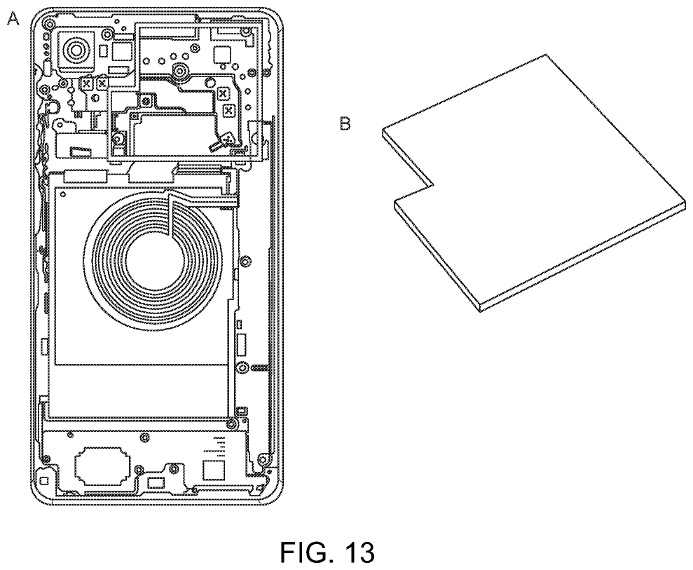

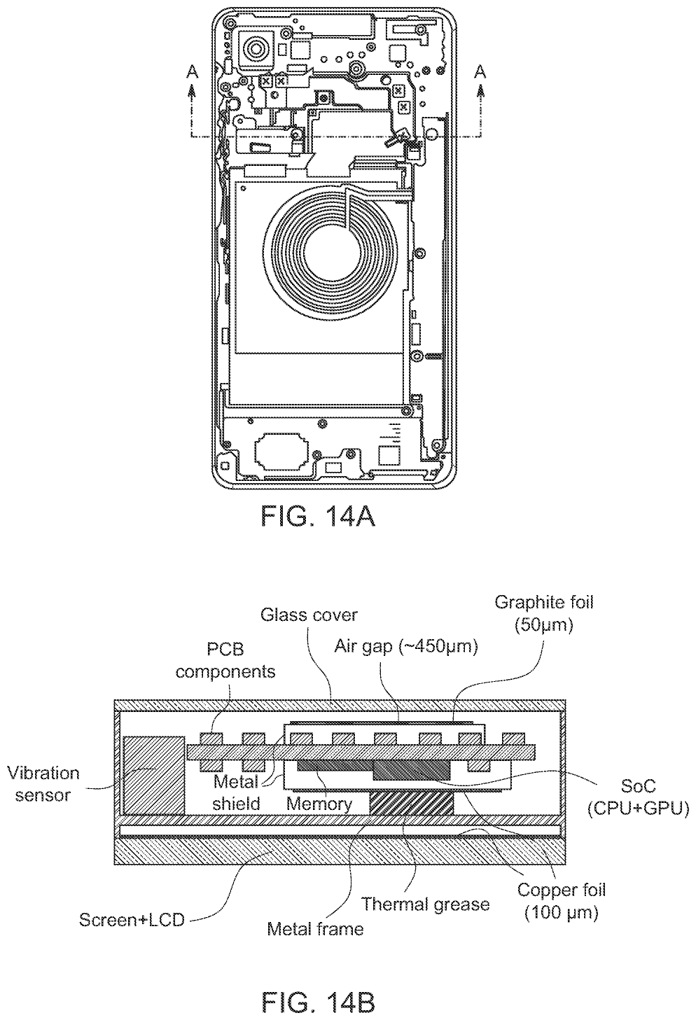

The part geometry, shown in FIG. 13, was chosen to maximize area with no or minimal disruption to internal components. The part area measured to be 1,825 mm². A cross section schematic through the thickness of the Pixel (of FIG. 14a) is depicted in FIG. 14b. Simulation results were analyzed to inform material configurations chosen for Pixel testing.

Results—Google Pixel 3XL 3DMark Stress Test

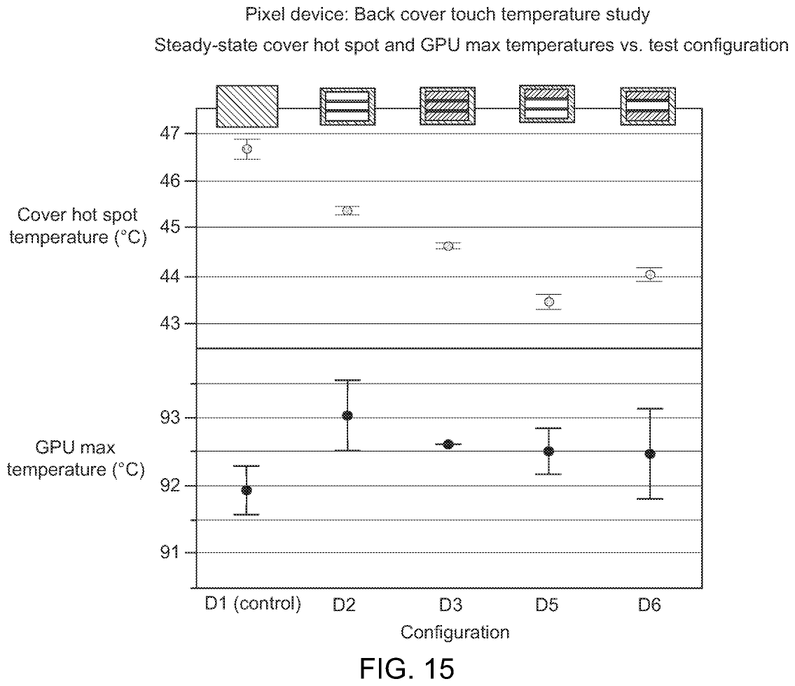

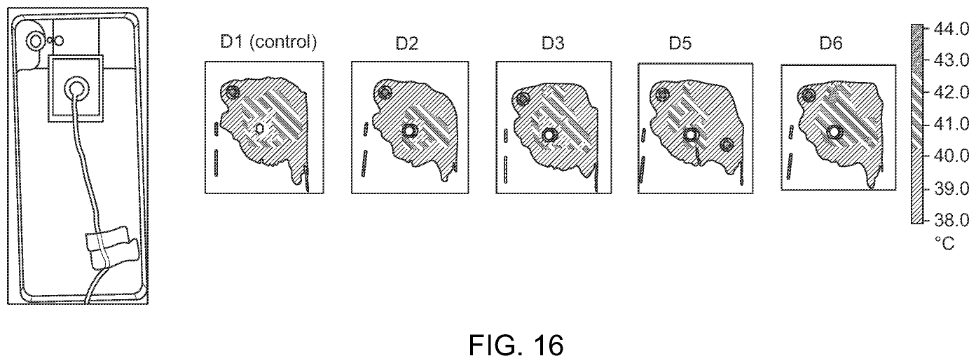

Back Cover Touch Temperature Study: Five (5) configurations were down selected from simulation testing and the configurations are illustrated in FIG. 12. The configurations selected for Pixel device testing were constructed with physical materials described above (the 110 μm samples and the double-sided tape); device test configurations were titled D1, D2, D3, D5, and D6 with D1 as the control scenario. The CPU and GPU frequencies were set at 2169.6 MHz and 675 MHz, respectively. Frequencies were recorded and verified at the end of each test run. Benchmark scores were recorded to show performance consistency across all test runs. Ambient temperatures in the still-air environment were held between 21.6° C. and 21.8° C. for all testing. All configurations were tested three times to steady-state (>90 minutes) in a randomized experiment. After each test run, the Pixel was cooled down to idle operating temperature and opened up to setup the next test run. The steady-state back cover touch temperatures and GPU max temperatures are shown in FIG. 15 (average of 3 measurements per configuration). IR images of the back cover are shown in FIG. 16. Depictions, thicknesses, and measured outputs (means and standard deviations) for all tested configurations are detailed in Table 3.

TABLE 3
Results from Back Cover Touch Temperature Study in Pixel

| | Cover Hot Spot | | Screen Hot Spot | | CPU Max | | GPU Max | | Slingshot | |
|---|---|---|---|---|---|---|---|---|---|---|
| | Temperature | | Temperature | | Temperature | | Temperature | | Extreme | |
| | (° C.) | | (° C.) | | (° C.) | | (° C.) | | Benchmark Score | |
| Configuration | | St. | | St. | | St. | | St. | | St. |
| (Thickness) | Mean | Dev. | Mean | Dev. | Mean | Dev. | Mean | Dev. | Mean | Dev. |
| D1 (control/ | 46.7 | 0.21 | 49.7 | 0.25 | 84.8 | 0.17 | 91.9 | 0.35 | 4374.3 | 1.15 |
| air only) | | | | | | | | | | |
| D2 | 45.4 | 0.12 | 50.5 | 0.10 | 86.1 | 0.51 | 93.0 | 0.51 | 4377.7 | 1.15 |
| (344 μm) | | | | | | | | | | |
| D3 | 44.6 | 0.06 | 50.1 | 0.10 | 85.4 | 0.65 | 92.6 | 0.00 | 4375.7 | 1.53 |
| (339 μm) | | | | | | | | | | |
| D5 | 43.5 | 0.15 | 49.9 | 0.26 | 85.6 | 0.17 | 92.5 | 0.35 | 4372.3 | 2.08 |
| (347 μm) | | | | | | | | | | |
| D6 | 44.0 | 0.15 | 49.9 | 0.26 | 85.6 | 0.51 | 92.5 | 0.67 | 4375.0 | 1.00 |
| (347 μm) | | | | | | | | | | |

All test configurations produced unique back cover touch temperatures with high precision, and all were distinctly lower than the control (Configuration D1). In agreement with the simulations, Configuration D5 presented the greatest back cover touch temperature reduction at 3.2° C. below the control. Configurations D6, D3, and D2 reduced the back cover touch temperature by 2.7° C., 2.1° C., and 1.3° C., respectively. Screen temperatures increased from the control by less than 1° C. for all configurations tested. CPU and GPU temperatures increased from the control by less than 1.5° C. for all configurations tested. The Pixel back cover touch temperature study results validate the directional trend of device cover surface temperature for the emulated configurations in the simulation study.

From Table 3 and FIGS. 15 and 16, the results are somewhat counterintuitive. The configurations D1 and D2 which had the highest insulation attributes, exhibited the highest back cover temperature (highest temperature hot spots). Conventional thinking is that the configurations with the greatest insulative attributes would minimize the hot spot temperature, which is clearly not true from the data presented. Further illustrated is that the control had the lowest GPU maximum temperature.

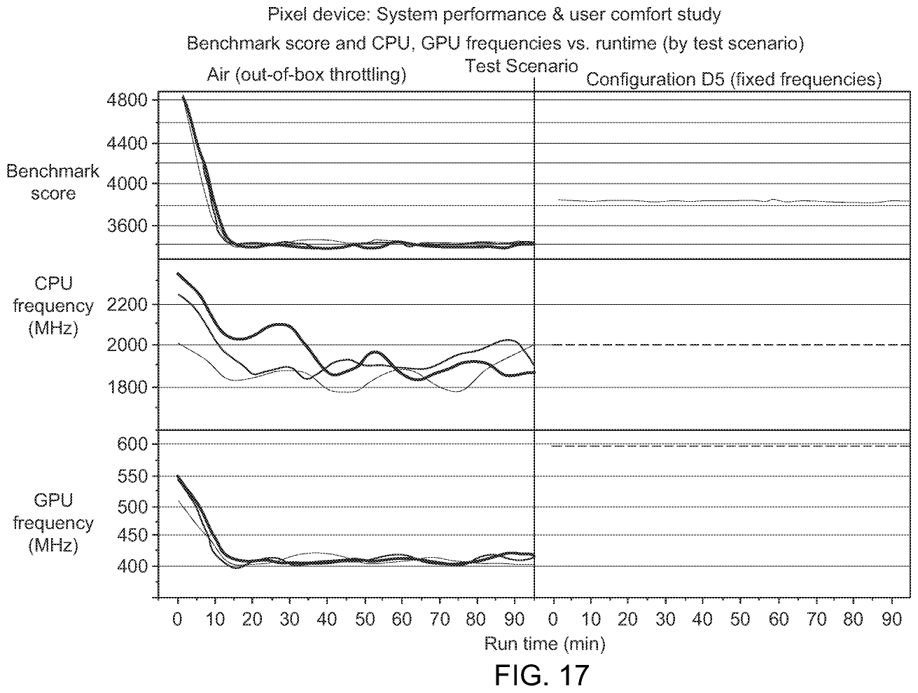

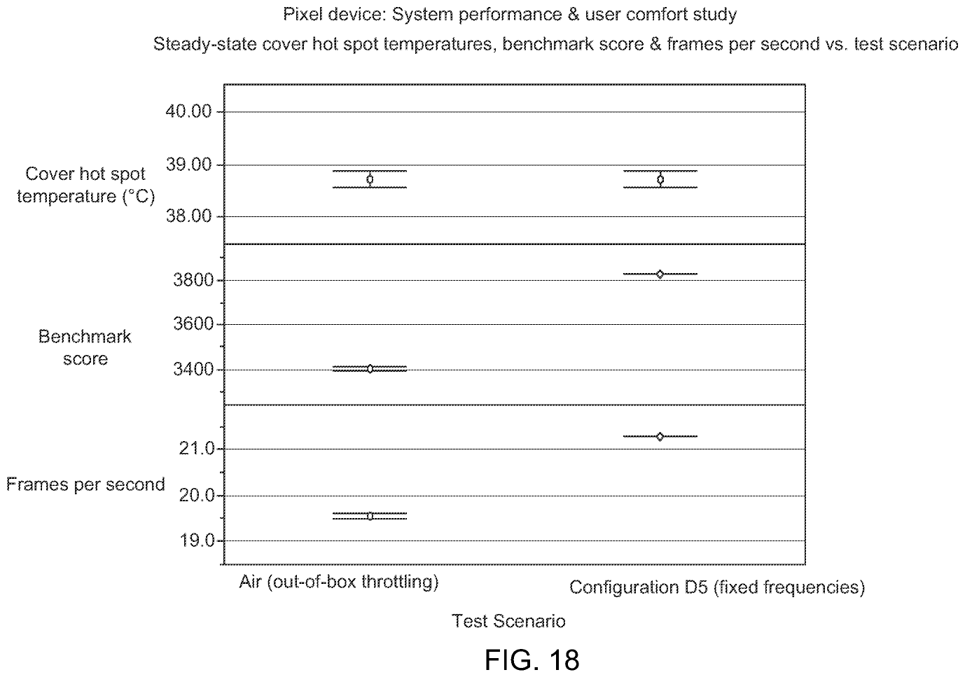

System Performance and User Comfort Study: A continuation study was created to determine the allowable system performance increase when enabled by graphite-insulation composites; configuration D5 was selected for this study. Out-of-the-box throttling conditions were restored to the Pixel and all thermal management systems were removed, leaving air only. The back cover touch temperature was measured during steady-state power throttling and recorded for 3 test runs. Configuration D5 was installed and frequencies were set to match the steady-state cover temperature from the throttled control runs. The appropriate frequencies for testing were determined to be 596 MHz and 1996.8 MHz for the CPU and GPU, respectively. Frequencies cover hot spot temperature, benchmark score, and frames per second were measured and compared between the two test scenarios. A smoothed plot of benchmark score, CPU frequency, and GPU frequency vs. run time for all 6 test runs is displayed in FIG. 17 (average of 3 measurements per test scenario). Mean steady-state cover temperature, benchmark score, and frames per second are shown in FIG. 18 (average of 3 measurements per test scenario). Details are summarized in Table 4.

TABLE 4
Results from System Performance and User Comfort Study in Pixel

| | Cover Temp | | Slingshot Extreme | | Frames | |
|---|---|---|---|---|---|---|
| | (° C.) | | Benchmark Score | | per Second | |
| Test Scenario | Mean | St. Dev. | Mean | St. Dev. | Mean | St. Dev. |
| Air (out-of-box | 38.7 | 0.15 | 3401.0 | 8.19 | 19.5 | 0.06 |
| throttling) | | | | | | |
| Configuration | 38.7 | 0.15 | 3822.7 | 3.06 | 21.3 | 0.00 |
| D5 (fixed | | | | | | |
| frequencies) | | | | | | |

The mean steady-state cover touch temperature achieved during out-of-box throttling is 38.7° C. in the controlled test environment at 21.7° C.; this temperature is related to UL 60950-1 mobile electronics touch (skin) temperatures at prolonged durations. In this scenario, the mean steady-state benchmark score and frames per second are 3401 and 19.5, respectively. When Configuration D5 is placed inside the back cover, the benchmark score is increased to 3822 and frames per second increased to 21.3, marking an approximately 12.4% increase in system performance, while maintaining the surface temperature limit set for the out-of-box throttling condition.

Conclusion: Graphite foils with ultra-high spreading capacity and insulation sheets with ultra-low thermal conductivity were combined in a thermally stressed Google Pixel 3XL to reduce steady-state surface touch (skin) temperatures (TS) by up to 3.2° C. with <1.2° C. increase in max junction temperature (Tj) as compared to single-component thermal solutions of graphite, insulation, and air. An axisymmetric conduction model was simulated in COMSOL to determine trends in surface temperature reductions of five (5) unique thermal management systems of comparable thickness (˜350 μm). Four (4) of these thermal management systems were fabricated, tested and validated experimentally in Google Pixel 3XL thermal stress testing. The composite yielding the greatest TS reduction was utilized to demonstrate an increase in steady-state system performance while maintaining a surface temperature suitable for user comfort and safety. The steady-state 3DMark Slingshot Extreme benchmark score increased from 3401 to 3823 resulting in a 12.4% increase in steady-state system performance.

All such weights as they pertain to listed ingredients are based on the active level and, therefore, do not include solvents or by-products that may be included in commercially available materials, unless otherwise specified.

All references to singular characteristics or limitations of the present disclosure shall include the corresponding plural characteristic or limitation, and vice versa, unless otherwise specified or clearly implied to the contrary by the context in which the reference is made. Thus, in the present disclosure, the words “a” or “an” are to be taken to include both the singular and the plural. Conversely, any reference to plural items shall, where appropriate, include the singular.

Unless otherwise indicated (e.g., by use of the term “precisely”), all numbers expressing quantities, properties such as molecular weight, reaction conditions, and so forth as used in the specification and claims are to be understood as being modified in all instances by the term “about.” Accordingly, unless otherwise indicated, the numerical properties set forth in the following specification and claims are approximations that may vary depending on the desired properties sought to be obtained in embodiments of the present invention.

If not stated herein thermal conductivities are provided at room temperature and standard pressure (1 atm) or alternatively at the appropriate testing conditions if a standard testing protocol is known such as ASTM D 5470 for through plane conductivity of flexible graphite articles.

All combinations of method or process steps as used herein can be performed in any order, unless otherwise specified or clearly implied to the contrary by the context in which the referenced combination is made.

All ranges and parameters, including but not limited to percentages, parts, and ratios, disclosed herein are understood to encompass any and all sub-ranges assumed and subsumed therein, and every number between the endpoints. For example, a stated range of “1 to 10” should be considered to include any and all subranges between (and inclusive of) the minimum value of 1 and the maximum value of 10; that is, all subranges beginning with a minimum value of 1 or more (e.g., 1 to 6.1), and ending with a maximum value of 10 or less (e.g., 2.3 to 9.4, 3 to 8, 4 to 7), and finally to each number 1, 2, 3, 4, 5, 6, 7, 8, 9, and 10 contained within the range.

The thermal management system and electronic device of the present disclosure can comprise, consist of, or consist essentially of the essential elements and limitations of the disclosure as described herein, as well as any additional or optional ingredients, components, or limitations described herein or otherwise useful in thermal management systems and/or electronic devices.

To the extent that the terms “include,” “includes,” or “including” are used in the specification or the claims, they are intended to be inclusive in a manner similar to the term “comprising” as that term is interpreted when employed as a transitional word in a claim. Furthermore, to the extent that the term “or” is employed (e.g., A or B), it is intended to mean “A or B or both A and B.” When the Applicant intends to indicate “only A or B but not both,” then the term “only A or B but not both” will be employed. Thus, use of the term “or” herein is the inclusive, and not the exclusive use.

In some embodiments, it may be possible to utilize the various inventive concepts in combination with one another. Additionally, any particular element recited as relating to a particularly disclosed embodiment should be interpreted as available for use with all disclosed embodiments, unless incorporation of the particular element would be contradictory to the express terms of the embodiment. Additional advantages and modifications will be readily apparent to those skilled in the art. Therefore, the disclosure, in its broader aspects, is not limited to the specific details presented therein, the representative apparatus, or the illustrative examples shown and described. Accordingly, departures may be made from such details without departing from the spirit or scope of the general inventive concepts.

### Exemplary Embodiments of the Present Disclosure

1. A thermal management system comprising:

a. a first element comprising a flexible graphite article having a thickness of more than 65 microns to 95 microns, an in-plane thermal conductivity of more than 700 W/mK up to 950 W/mK, and a through-plane thermal conductivity of less than 6 W/mK;

b. a second element adjacent the first element, the second element comprising an insulation material having a through-plane thermal conductivity of less than 0.025 W/mK, including a through-plane thermal conductivity of 0.01 W/mK to 0.0249 W/mK, a through-plane thermal conductivity of 0.015 W/mK to 0.0249 W/mK, or a through-plane thermal conductivity of 0.02 W/mK to 0.0249 W/mK; and

c. an optional third element adjacent the second element and opposed to the first element, the third element comprising a flexible graphite article having a thickness of at least 65 microns up to 500 microns, an in-plane thermal conductivity of more than 700 W/mK, and a through-plane thermal conductivity of less than 6 W/mK.

2. The thermal management system of paragraph 1, wherein the thermal management system comprises the third element.
3. The thermal management system of paragraph 2, wherein the third element has an in-plane thermal conductivity of at least 1000 W/mK, including an in-plane thermal conductivity of 1000 W/mK to 1500 W/mK, an in-plane thermal conductivity of 1025 W/mK to 1400 W/mK, an in-plane thermal conductivity of 1050 W/mK to 1300 W/mK, or an in-plane thermal conductivity of 1100 W/mK to 1200 W/mK.
4. The thermal management system of any one of paragraphs 1 to 3, wherein at least one of the first element and the third element is monolithic.
5. The thermal management system of any one of paragraphs 1 to 4, wherein the second element has a thickness of no more than 2 mm, including a thickness of 1 micron to 2 mm, a thickness of 5 microns to 2 mm, a thickness of 10 microns to 2 mm, a thickness of 20 microns to 2 mm, a thickness of 30 microns to 2 mm, a thickness of 50 microns to 2 mm, a thickness of 70 microns to 2 mm, a thickness of 0.1 mm to 1.5 mm, a thickness of 0.1 mm to 1 mm, a thickness of 0.1 mm to 0.5 mm, a thickness of 0.1 mm to 0.3 mm, or a thickness of 0.1 mm to 0.25 mm.
6. The thermal management system of any one of paragraphs 1 to 5, wherein the second element comprises an aerogel.
7. An electronic device comprising:

a. a heat source;

b. an external surface; and

c. the thermal management system of any one of paragraphs 1 to 6, wherein either the first element or the third element is in operative thermal communication with the heat source and the other of the first element or the third element faces the external surface.

8. The electronic device of paragraph 7, wherein an air gap is between the external surface and the element facing the external surface.
9. The electronic device of paragraph 7, wherein a portion of the external surface is in physical contact with the element facing the external surface.
10. The electronic device of paragraph 9, wherein the portion of the external surface has the same surface area as the surface area of the element facing the external surface and the portion of the external surface is devoid of an offset.
11. The electronic device of any one of paragraphs 7 to 10, wherein a surface area of the element in operative thermal communication with the heat source is at least 1.5 times greater than the surface area of that portion of the surface of the heat source which is in operative thermal communication with the element.
12. A thermal management system comprising:

a. a first element comprising a flexible graphite article having a thickness of more than 100 microns up to 500 microns, an in-plane thermal conductivity of more than 1000 W/mK, and a through-plane thermal conductivity of less than 6 W/mK;

b. a second element adjacent the first element, the second element comprising an insulation material having a through-plane thermal conductivity of less than 0.025 W/mK, including a through-plane thermal conductivity of 0.01 W/mK to 0.0249 W/mK, a through-plane thermal conductivity of 0.015 W/mK to 0.0249 W/mK, or a through-plane thermal conductivity of 0.02 W/mK to 0.0249 W/mK; and

c. an optional third element adjacent the second element and opposed to the first element, the third element comprising a flexible graphite article having a thickness of more than 100 microns up to 500 microns and an in-plane thermal conductivity of more than 1000 W/mK.

13. The thermal management system of paragraph 12, wherein the second element has a thickness of no more than 2 mm, including a thickness of 1 micron to 2 mm, a thickness of 5 microns to 2 mm, a thickness of 10 microns to 2 mm, a thickness of 20 microns to 2 mm, a thickness of 30 microns to 2 mm, a thickness of 50 microns to 2 mm, a thickness of 70 microns to 2 mm, a thickness of 0.1 mm to 1.5 mm, a thickness of 0.1 mm to 1 mm, a thickness of 0.1 mm to 0.5 mm, a thickness of 0.1 mm to 0.3 mm, or a thickness of 0.1 mm to 0.25 mm.
14. The thermal management system of paragraph 12 or paragraph 13, wherein at least one of the first element or the third element has a thickness of at least 125 microns.
15. The thermal management system of any one of paragraphs 12 to 14, wherein at least one of the first element and the third element is monolithic.
16. The thermal management system of any one of paragraphs 12 to 15, wherein the second element comprises an aerogel.
17. An electronic device comprising:

a. a heat source;

b. an external surface; and

c. the thermal management system of any one of claims 12 to 16, wherein either the first element or the third element is in operative thermal communication with the heat source and the other of the first element or the third element faces the external surface.

18. The electronic device of paragraph 17, wherein an air gap is between the external surface and the element facing the external surface.
19. The electronic device of paragraph 17, wherein a portion of the external surface is in physical contact with the element facing the external surface.
20. The electronic device of paragraph 19, wherein the portion of the external surface has the same surface area as the surface area of the element facing the external surface and the portion of the external surface is devoid of an offset.
21. The electronic device of any one of paragraphs 17 to 20, wherein a surface area of the element in operative thermal communication with the heat source is at least 1.5 times greater than the surface area of that portion of the surface of the heat source which is in operative thermal communication with the element.
22. The electronic device of any one of paragraphs 17 to 21, wherein a temperature differential between a first point on a surface of the element facing the external surface and a second point on the surface of the element facing the external surface is less than about 2.5° C., wherein the first point and the second point are separated by no more than 50 mm.
23. The electronic device of paragraph 22, wherein the first point and the second point are separated by at least 35 mm.

24. The electronic device of any one of paragraphs 17 to 23, wherein a temperature differential between a first point on a surface of the element in operative thermal communication with the heat source and a second point on a surface of the element facing the external surface is more than 1.5° C., wherein the first point and the second point lie on a common axis.

25. A thermal management system comprising:

a. a first element comprising a flexible graphite article having a thickness of at least 100 microns up to 500 microns, an in-plane thermal conductivity of more than 1000 W/mK, and a through-plane thermal conductivity of less than 6 W/mK;

b. a second element adjacent the first element, the second element comprising an insulation material having a through-plane thermal conductivity of less than 0.025 W/mK, including a through-plane thermal conductivity of 0.01 W/mK to 0.0249 W/mK, a through-plane thermal conductivity of 0.015 W/mK to 0.0249 W/mK, or a through-plane thermal conductivity of 0.02 W/mK to 0.0249 W/mK; and

c. an optional third element adjacent the second element and opposed to the first element, the third element comprising a flexible graphite article having a thickness of at least 100 microns up to 500 microns and an in-plane thermal conductivity of more than 1000 W/mK.

26. The thermal management system of paragraph 25, wherein at least one of the first element and the third element is monolithic.
27. The thermal management system of paragraph 25 or paragraph 26, wherein the second element has a thickness of less than 2 mm, including a thickness of 1 micron to 2 mm, a thickness of 5 microns to 2 mm, a thickness of 10 microns to 2 mm, a thickness of 20 microns to 2 mm, a thickness of 30 microns to 2 mm, a thickness of 50 microns to 2 mm, a thickness of 70 microns to 2 mm, a thickness of 0.1 mm to 1.5 mm, a thickness of 0.1 mm to 1 mm, a thickness of 0.1 mm to 0.5 mm, a thickness of 0.1 mm to 0.3 mm, or a thickness of 0.1 mm to 0.25 mm.
28. The thermal management system of any one of paragraphs 25 to 27, wherein the second element comprises an aerogel.
29. An electronic device comprising:

a. a heat source;

b. an external surface; and

c. the thermal management system of any one of paragraphs 25 to 28, wherein either the first element or the third element is in operative thermal communication with the heat source and the other of the first element or the third element faces the external surface.

30. The electronic device of paragraph 29, wherein an air gap is between the external surface and the element facing the external surface.
31. The electronic device of paragraph 29, wherein a portion of the external surface is in physical contact with the element facing the external surface.
32. The electronic device of paragraph 31, wherein the portion of the external surface has the same surface area as the surface area of the element facing the external surface and the portion of the external surface is devoid of a setoff.
33. The electronic device of any one of paragraphs 29 to 32, wherein a surface area of the element in operative thermal communication with the heat source is at least 1.5 times greater than the surface area of that portion of the surface of the heat source which is in operative thermal communication with the element.
34. The electronic device of any one of paragraphs 29 to 33, wherein a temperature differential between a first point on a surface of the element facing the external surface and a second point on the surface of the element facing the external surface is less than about 2.5° C., wherein the first point and the second point are separated by no more than 50 mm.
35. The electronic device of paragraph 34, wherein the first point and the second point are separated by at least 35 mm.
36. The electronic device of any one of paragraphs 29 to 35, wherein a temperature differential between a first point on a surface of the element in operative thermal communication with the heat source and a second point on a surface of the element facing the external surface is more than 1.5° C., wherein the first point and the second point lie on a common axis.
37. A thermal management system comprising:

a. a first element comprising a flexible graphite article having a thickness of more than 100 microns up to 500 microns, an in-plane thermal conductivity of more than 1000 W/mK, and a through-plane thermal conductivity of less than 6 W/mK;

b. a second element adjacent the first element, the second element comprising an insulation material having a through-plane thermal conductivity of less than 0.05 W/mK, including a through-plane thermal conductivity of 0.01 W/mK to 0.049 W/mK, a through-plane thermal conductivity of 0.015 W/mK to 0.049 W/mK, a through-plane thermal conductivity of 0.02 W/mK to 0.049 W/mK, a through-plane thermal conductivity of 0.025 W/mK to 0.049 W/mK, a through-plane thermal conductivity of 0.03 W/mK to 0.049 W/mK, a through-plane thermal conductivity of 0.035 W/mK to 0.049 W/mK, a through-plane thermal conductivity of 0.04 W/mK to 0.049 W/mK, or a through-plane thermal conductivity of 0.045 W/mK to 0.049 W/mK; and

c. an optional third element adjacent the second element and opposed to the first element, the third element comprising a flexible graphite article having a thickness of more than 100 microns up to 500 microns and an in-plane thermal conductivity of more than 1000 W/mK.

38. The thermal management system of paragraph 37, wherein at least one of the first element and the third element is monolithic.
39. The thermal management system of paragraph 37 or paragraph 38, wherein the second element has a thickness of no more than 2 mm, including a thickness of 1 micron to 2 mm, a thickness of 5 microns to 2 mm, a thickness of 10 microns to 2 mm, a thickness of 20 microns to 2 mm, a thickness of 30 microns to 2 mm, a thickness of 50 microns to 2 mm, a thickness of 70 microns to 2 mm, a thickness of 0.1 mm to 1.5 mm, a thickness of 0.1 mm to 1 mm, a thickness of 0.1 mm to 0.5 mm, a thickness of 0.1 mm to 0.3 mm, or a thickness of 0.1 mm to 0.25 mm.
40. The thermal management system of any one of paragraphs 37 to 39, wherein the second element comprises at least one of an aerogel or an expanded polytetrafluoroethylene membrane.
41. An electronic device comprising:

a. a heat source;

b. an external surface; and

c. the thermal management system of any one of paragraphs 37 to 40, wherein either the first element or the third element is in operative thermal communication with the heat source and the other of the first element or the third element faces the external surface.

42. The electronic device of paragraph 41, wherein an air gap is between the external surface and the element facing the external surface.
43. The electronic device of paragraph 41, wherein a portion of the external surface is in physical contact with the element facing the external surface.

44. The electronic device of paragraph 43, wherein the portion of the external surface has the same surface area as the surface area of the element facing the external surface and the portion of the external surface is devoid of an offset.

45. The electronic device of any one of paragraph 41 to 44, wherein a surface area of the element in operative thermal communication with the heat source is at least 1.5 times greater than the surface area of that portion of the surface of the heat source which is in operative thermal communication with the element.
46. A thermal management system comprising:

a. a first element comprising a flexible graphite article having a thickness of more than 100 microns up to 500 microns, an in-plane thermal conductivity of more than 1000 W/mK, and a through-plane thermal conductivity of less than 6 W/mK; and

b. a second element comprising an insulation material having a through-plane thermal conductivity of less than 0.15 W/mK, including a through-plane thermal conductivity of 0.01 W/mK to 0.149 W/mK, a through-plane thermal conductivity of 0.015 W/mK to 0.149 W/mK, a through-plane thermal conductivity of 0.02 W/mK to 0.149 W/mK, a through-plane thermal conductivity of 0.025 W/mK to 0.149 W/mK, a through-plane thermal conductivity of 0.03 W/mK to 0.149 W/mK, a through-plane thermal conductivity of 0.035 W/mK to 0.149 W/mK, a through-plane thermal conductivity of 0.04 W/mK to 0.149 W/mK, a through-plane thermal conductivity of 0.045 W/mK to 0.149 W/mK, a through-plane thermal conductivity of 0.05 W/mK to 0.149 W/mK, a through-plane thermal conductivity of 0.06 W/mK to 0.149 W/mK, a through-plane thermal conductivity of 0.07 W/mK to 0.149 W/mK, a through-plane thermal conductivity of 0.08 W/mK to 0.149 W/mK, a through-plane thermal conductivity of 0.09 W/mK to 0.149 W/mK, a through-plane thermal conductivity of 0.1 W/mK to 0.149 W/mK, a through-plane thermal conductivity of 0.11 W/mK to 0.149 W/mK, a through-plane thermal conductivity of 0.12 W/mK to 0.149 W/mK, a through-plane thermal conductivity of 0.13 W/mK to 0.149 W/mK, or a through-plane thermal conductivity of 0.14 W/mK to 0.149 W/mK, wherein a thickness of the second element comprises at least the same thickness of the first element up to no more than ten times the thickness of the first element.

47. The thermal management system of paragraph 46, wherein the insulation material comprises at least one of an aerogel or a porous polymer matrix.
48. The thermal management system of paragraph 46 or paragraph 47, wherein the through-plane thermal conductivity of the insulation material comprises less than 0.05 W/mK, including a through-plane thermal conductivity of 0.01 W/mK to 0.049 W/mK, a through-plane thermal conductivity of 0.015 W/mK to 0.049 W/mK, a through-plane thermal conductivity of 0.02 W/mK to 0.049 W/mK, a through-plane thermal conductivity of 0.025 W/mK to 0.049 W/mK, a through-plane thermal conductivity of 0.03 W/mK to 0.049 W/mK. a through-plane thermal conductivity of 0.035 W/mK to 0.049 W/mK, a through-plane thermal conductivity of 0.04 W/mK to 0.049 W/mK, or a through-plane thermal conductivity of 0.045 W/mK to 0.049 W/mK.
49. The thermal management system of any one of paragraphs 46 to 48, wherein the thickness of the second element comprises no more than seven times the thickness of the first element.
50. The electronic device of any one of paragraphs 46 to 48, wherein the thickness of the second element comprises no more than three times the thickness of the first element.
51. An electronic device comprising the thermal management system of any one of paragraphs 46 to 50 and a heat source, wherein the thermal management system is in operative thermal communication with the heat source and wherein one of the first element or the second element of the thermal management system is aligned adjacent the heat source.
52. The electronic device of paragraph 51, further comprising an air gap between the heat source and the thermal management system.
53. A thermal management system comprising:

a. flexible graphite first element having a thickness of at least 100 μm, an in-plane thermal conductivity of more than 1000 W/mK and a through-plane thermal conductivity of no more than 6 W/mK and

b. an insulation material second element adjacent the first element, the second element having a through-plane thermal conductivity of no more than 0.05 W/mK, including a through-plane thermal conductivity of 0.025 W/mK to 0.05 W/mK, a through-plane thermal conductivity of 0.03 W/mK to 0.05 W/mK, a through-plane thermal conductivity of 0.035 W/mK to 0.05 W/mK, a through-plane thermal conductivity of 0.04 W/mK to 0.05 W/mK, or a through-plane thermal conductivity of 0.045 W/mK to 0.05 W/mK.

1. A thermal management system comprising:
a. flexible graphite first element having a thickness of at least 100 μm, an in-plane thermal conductivity of more than 1000 W/mK and a through-plane thermal conductivity of no more than 6 W/mK and
b. an insulation material second element adjacent the first element, the second element having a through-plane thermal conductivity of no more than 0.05 W/mK.

2. The thermal management system of claim 1, wherein the flexible graphite first element comprises a monolithic layer.

3. The thermal management system of claim 1, wherein a thickness of the insulation material second element comprises less than 2 mm.

4. The thermal management system of claim 1, wherein the insulation material second element comprises an aerogel or a porous polymer matrix.

5. The thermal management system of claim 1, wherein a surface area of the flexible graphite first element is at least 1.1 times larger than a surface area of the insulation material second element.

6. The thermal management system of claim 1, wherein a thickness of the insulation material second element comprises no more than 10 times the thickness of the flexible graphite first element.

7. An electronic device comprising:
a. a heat source;
b. an external surface; and
c. the thermal management system of claim 1 located between the heat source and the external surface, wherein the thermal management system is in thermal communication with the heat source.

8. The electronic device of claim 7, further comprising an air gap between at least one of the external surface or the heat source and the thermal management system.

9. The electronic device of claim 7, wherein a portion of the external surface is in physical contact with the thermal management system.

10. The electronic device of claim 7, wherein the heat source is in physical contact with at least a portion of the thermal management system.

11. The electronic device of claim 7, wherein the insulation material second element of the thermal management system is oriented facing the heat source.

12. The electronic device of claim 7, wherein the flexible graphite first element of the thermal management system is oriented facing the heat source.

13. A thermal management system comprising:
a. a flexible graphite first element having a thickness of at least 100 μm, an in-plane thermal conductivity of at least 1000 W/mK and a through-plane thermal conductivity of less than 6 W/mK;
b. an insulation material second element adjacent the flexible graphite first element, the second element having a through-plane thermal conductivity of less than 0.05 W/mK; and
c. a flexible graphite third element adjacent the second element, having a thickness of at least 100 μm, an in-plane thermal conductivity of at least 1000 W/mK and a through-plane thermal conductivity of no more than 6 W/mK.

14. The thermal management system of claim 13, wherein at least one of the flexible graphite first element or the flexible graphite third element or both is monolithic.

15. The thermal management system of claim 13, wherein a thickness of the insulation material second element comprises less than 2 mm.

16. The thermal management system of claim 13, wherein the insulation material second element comprises an aerogel or a porous polymer matrix.

17. The thermal management system of claim 13, wherein a surface area of at least one of the flexible graphite first element, the flexible graphite third element or both is at least 1.1 times larger than a surface area of the insulation material second element.

18. The thermal management system of claim 13, wherein a thickness of the insulation material second element comprises up to 10 times the thickness of the thickest of the flexible graphite first element or the flexible graphite third element.

19. An electronic device comprising:
a. a heat source;
b. an external surface; and
c. the thermal management system of claim 13, wherein the thermal management system is located between the heat source and the external surface.

20. The electronic device of claim 19, wherein an air gap is present on at least one side of the thermal management system.

21. The electronic device of claim 19, wherein the external surface is in physical contact with at least a portion of the thermal management system.

22. The electronic device of claim 19, wherein the heat source is in physical contact with at least a portion of the thermal management system.

23. The thermal management system of claim 1, wherein the system further comprises a flexible graphite third element adjacent the second element, having a thickness of at least 100 μm, an in-plane thermal conductivity of at least 1000 W/mK and a through-plane thermal conductivity of no more than 6 W/mK.
